(19) United States
(12) Patent Application Publication
(10) Pub. No.: US 2026/0010070 A1
(43) Pub. Date: Jan. 8, 2026

(54) RESIST COMPOSITION AND METHOD OF FORMING PATTERN USING THE SAME

(71) Applicant: Samsung Electronics Co., Ltd., Suwon-si (KR)

(72) Inventors: Changheon LEE, Suwon-si (KR); Haengdeog KOH, Suwon-si (KR); Yoonhyun KWAK, Suwon-si (KR); Beomseok KIM, Suwon-si (KR); Hyeran KIM, Suwon-si (KR); Sunyoung LEE, Suwon-si (KR); Kyuhyun IM, Suwon-si (KR); Jinwon JEON, Suwon-si (KR); Jungha CHAE, Suwon-si (KR); Hyunseok CHOI, Suwon-si (KR)

(73) Assignee: Samsung Electronics Co., Ltd., Suwon-si (KR)

(21) Appl. No.: 18/973,373

(22) Filed: Dec. 9, 2024

(30) Foreign Application Priority Data
Jul. 3, 2024 (KR) 10-2024-0087806

(51) Int. Cl. G03F 7/004; G03F 7/039; G03F 7/20

(52) U.S. Cl. CPC G03F 7/0042; G03F 7/0392; G03F 7/2006

(57) ABSTRACT

Provided are a resist composition and a method of forming a pattern using the same. The resist composition may include an organometallic compound represented by Formula 1 and a polymer including a first repeating unit represented by Formula 2 and a second repeating unit represented by Formula 3:

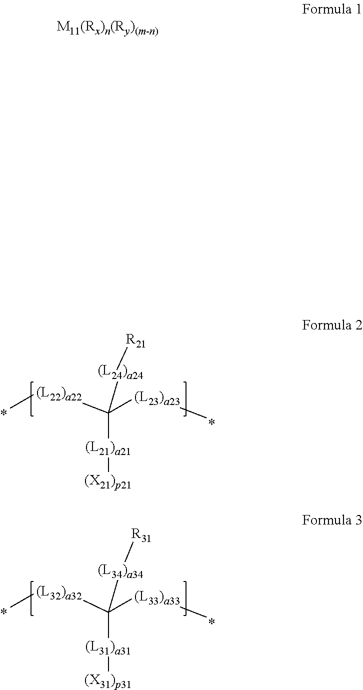

wherein, in Formulae 1 to 3,
M₁₁, Rₓ, R_{y}, n, m, L₂₁ to L₂₄, a21 to a24, R₂₁, X₂₁, p21, L₃₁ to L₃₄, a31 to a34, R₃₁, X₃₁, and p31 are as described in the present specification.

### CROSS-REFERENCE TO RELATED APPLICATION

This application is based on and claims priority under 35 U.S.C. § 119 to Korean Patent Application No. 10-2024-0087806, filed on Jul. 3, 2024, in the Korean Intellectual Property Office, the disclosure of which is incorporated by reference herein in its entirety.

### BACKGROUND

### 1. Field

The disclosure relates to a resist composition and/or a method of forming a pattern using the same.

### 2. Description of the Related Art

In semiconductor manufacturing, resists may have physical properties that change in response to light and resists may be used to form fine patterns. From among these resists, chemically amplified resists may be used. A chemically amplified resist enables patterning by changing the solubility of a base resin in a developer by reacting an acid, which may be formed by a reaction between light and a photoacid generator, with the base resin again.

However, in the case of a chemically amplified resist, a decrease in pattern uniformity and/or surface roughness may occur as the formed acid diffuses to a non-exposed region. Also, as semiconductor processes are miniaturized, it may be difficult to control the diffusion of acids, and thus there may be a need to develop a new type of resist.

Recently, in order to overcome the limits of chemically amplified resists, attempts have been made to develop materials of which physical properties change due to exposure to light. However, the dose required for exposure may be high.

### SUMMARY

Provided are a resist composition having improved storage stability and/or physical properties that change even with low doses of exposure and providing patterns with improved resolution, and/or a method of forming a pattern using the resist composition.

Additional aspects will be set forth in part in the description which follows and, in part, will be apparent from the description, or may be learned by practice of the presented embodiments of the disclosure.

According to an embodiment of the disclosure, a resist composition may include an organometallic compound represented by Formula 1 and a polymer including a first repeating unit represented by Formula 2 and a second repeating unit represented by Formula 3:

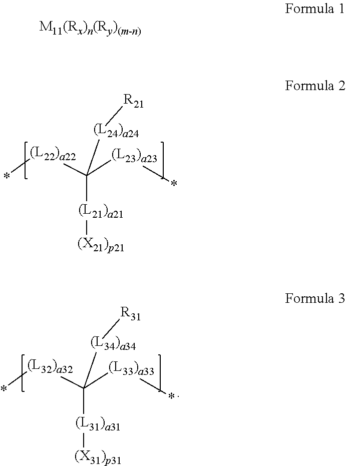

In Formulae 1 to 3,
M₁₁ may be indium (In), tin (Sn), antimony (Sb), tellurium (Te), thallium (Tl), lead (Pb), bismuth (Bi), or polonium (Po),
Rₓ may be *-(L₁)ₐ₁-(R₁)_{b1},
R_{y} may be *—Y₁—X₁,
n may be an integer from 1 to 6,
m may be an integer from 0 to 6,
m−n may be greater than or equal to 0,
a plurality of Rₓ may be identical to or different from each other,
a plurality of R_{y} may be identical to or different from each other,
L₁ may be a single bond or a linear, branched, or cyclic C₁-C₃₀ divalent hydrocarbon group,
a₁ may be an integer from 1 to 4,
R₁ may be a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group, wherein two adjacent groups among a plurality of R₁ are optionally bound together to form a condensed ring,
b1 may be an integer from 1 to 4,
Y₁ may be O, O(C═O), S, S(C═O), NX₁₄, or N(C═O),
X₁ and X₁₄ may each independently be hydrogen, deuterium, or a linear, branched, or cyclic C₁-C₃₀ monovalent hydrocarbon group that optionally includes a heteroatom,
L₂₁ to L₂₃ may each independently be a single bond, O, S, C(═O), C(═O)O, OC(═O), C(═O)NR₂₂, NR₂₂C(═O), S(═O), S(═O)₂, S(═O)₂O, OS(═O)₂, or a linear, branched, or cyclic C₁-C₃₀ divalent hydrocarbon group that optionally includes a heteroatom,
L₃₁ to L₃₃ may each independently be a single bond, OO, S, C(═O), C(═O)O, OC(═O), C(═O)NR₂₂, NR₂₂C(═O), S(═O), S(═O)₂, S(═O)₂O, OS(═O)₂, or a linear, branched, or cyclic C₁-C₃₀ divalent hydrocarbon group that optionally includes a heteroatom,
L₂₄ may be C(═O)O, OC(═O), C(═O)S, SC(═O), OC(═O)O, SC(═O)O, OC(═O)S, SC(═O)S, C(═O)NR₂₂, NR₂₂C(═O), OC(═O)NR₂₂, or NR₂₂C(═O)O,
L₃₄ may be C(═O)O, OC(═O), C(═O)S, SC(═O), OC(═O)O, SC(═O)O, OC(═O)S, SC(═O)S, C(═O)NR₃₂, NR₃₂C(═O), OC(═O)NR₃₂, or NR₃₂C(═O)O,
a21 to a24 and a31 to a34 may each independently be an integer from 1 to 4,
R₂₁, R₂₂, R₃₁, and R₃₂ may each independently be hydrogen, deuterium, or a linear, branched, or cyclic C₁-C₃₀ monovalent hydrocarbon group that optionally includes a heteroatom,
X₂₁ may be a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
X₃₁ may be an electron-withdrawing group,
p21 and p31 may each independently be an integer from 1 to 5, and
* indicates a binding site to a neighboring atom.

According to an embodiment of the disclosure, a method of forming a pattern may include forming a resist film by applying the resist composition on a substrate, exposing at least a portion of the resist film with high-energy rays to provide an exposed resist film, and developing the exposed resist film by using a developer.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart illustrating a method of forming a pattern according to an embodiment;

FIGS. 2A to 2C are each a side cross-sectional view illustrating a method of forming a pattern according to an embodiment;

FIGS. 3A to 3E are each a side cross-sectional view illustrating a method of forming a patterned structure according to an embodiment; and

FIGS. 4A to 4E are each a side cross-sectional view illustrating a method of manufacturing a semiconductor device according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects. As used herein, the term “and/or” includes any and all combinations of one or more of the associated listed items. Expressions such as “at least one of,” when preceding a list of elements, modify the entire list of elements and do not modify the individual elements of the list. For example, “at least one of A, B, and C,” and similar language (e.g., “at least one selected from the group consisting of A, B, and C” and “at least one of A, B, or C”) may be construed as A only, B only, C only, or any combination of two or more of A, B, and C, such as, for instance, ABC, AB, BC, and AC.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

The disclosure may undergo various modifications and may have various embodiments. Accordingly, specific embodiments are illustrated in the drawings and described in detail in the detailed description. However, this is not intended to limit the disclosure to a specific embodiment, and should be understood to include all modifications, equivalents, or substitutes included in the spirit and technical scope of the disclosure. In describing the disclosure, when it is determined that a detailed description of related known technologies may make the gist of the disclosure unclear, the detailed description will be omitted.

The terms “first”, “second”, “third”, etc. may be used to describe various elements, but are used only for the purpose of distinguishing one element from another element, and the order or type of the elements are not limited.

Throughout this specification, a portion of a layer, film, region, plate, etc., described as being “on” or “above” another portion thereof may be positioned directly above, below, to the left or right of, while in contact, as well as above, below, to the left or light of, while in a non-contact

Singular expressions include plural expressions unless the context clearly dictates otherwise. Terms such as “include” or “have” are intended to indicate the presence of features, numbers, steps, operations, elements, parts, components, materials, or combinations thereof described in the specification unless otherwise stated, and it should be understood that the terms do not preclude the possibility of the presence or addition of one or more other features, numbers, steps, operations, elements, parts, components, materials, or combinations thereof.

Whenever a range of values is recited, that range includes all values that fall within that range, as if explicitly written out, and further includes the boundaries of the range. Thus, the range of “X to Y” includes all values between X and Y, and also includes X and Y.

The term “Cₓ-C_{y}” as used herein refers to a case where the number of carbons constituting the substituent is x to y. For example, the term “C₁-C₆” refers to a case where the number of carbons constituting the substituent is 1 to 6, and the term “C₆-C₂₀” refers to a case where the number of carbons constituting the substituent is 6 to 20.

The term “monovalent hydrocarbon group” as used herein refers to a monovalent residue derived from an organometallic compound including carbon and hydrogen or a derivative of the organometallic compound, and examples thereof may include: a linear or branched alkyl group (e.g., a methyl group, an ethyl group, a propyl group, an isopropyl group, a butyl group, an isobutyl group, a sec-butyl group, a tert-butyl group, a pentyl group, a neopentyl group, a hexyl group, a heptyl group, a 2-ethylhexyl group, and a nonyl group); a monovalent saturated cyclic aliphatic hydrocarbon group (e.g., a cycloalkyl group) (e.g., a cyclopentyl group, a cyclohexyl group, a cyclopentylmethyl group, a cyclopentylethyl group, a cyclopentylbutyl group, a cyclohexylmethyl group, a cyclohexylethyl group, a cyclohexylbutyl group, a 1-adamantyl group, a 2-adamantyl group, a 1-adamantylmethyl group, a norbornyl group, a norbornylmethyl group, a tricyclotricyclodecanyl group, a tetracyclododecanyl group, a tetracyclododecanylmethyl group, and a dicyclohexylmethyl group); a monovalent unsaturated aliphatic hydrocarbon group (e.g., an alkenyl group, an alkynyl group, and an allyl group); a monovalent unsaturated cyclic aliphatic hydrocarbon group (e.g., a cycloalkenyl group and a 3-cyclohexenyl group); an aryl group (e.g., a phenyl group, a 1-napthyl group, and a 2-napthyl group); an arylalkyl group (e.g., a benzyl group and a diphenylmethyl group); a heteroatom-containing monovalent hydrocarbon group (e.g., a tetrahydrofuranyl group, a methoxymethyl group, an ethoxy methyl group, a methylthiomethyl group, an acetamidemethyl group, a trifluoroethyl group, a (2-methoxyethoxy)methyl group, an acetoxymethyl group, a 2-carboxyl-1-cyclohexyl group, a 2-oxopropyl group, a 4-oxo-1-adamantyl group, and a 3-oxocyclohexyl group); or any combination thereof. Also, among these groups, some hydrogen atoms may be substituted with a moiety including a heteroatom such as an oxygen atom, a sulfur atom, a nitrogen atom, a phosphorus atom, or a halogen atom, or some carbon atoms may be substituted with a moiety including a heteroatom such as an oxygen atom, a sulfur atom, a nitrogen atom, or a phosphorus atom. Accordingly, these groups may include a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, and the like.

The term “divalent hydrocarbon group” as used herein refers to a divalent residue in which one hydrogen of the monovalent hydrocarbon group is replaced by a binding site to a neighboring atom. The divalent hydrocarbon group may include, for example, either linear or branched, an alkylene group, a cycloalkylene group, an alkenylene group, an alkynylene group, a cycloalkylene group, an arylene group, or a group in which some carbon atoms of the aforementioned groups are replaced by heteroatoms.

The term “alkyl group” as used herein refers to a linear or branched saturated aliphatic hydrocarbon monovalent group, and examples thereof may include a methyl group, an ethyl group, a propyl group, an isobutyl group, a sec-butyl group, a tert-butyl group, a pentyl group, an iso-amyl group, a hexyl group, and the like. The term “alkylene group” used as herein refers to a linear or branched saturated aliphatic divalent hydrocarbon group, and examples thereof may include a methylene group, an ethylene group, a propylene group, a butylene group, an isobutyl group, and the like.

The term “halogenated alkyl group” as used herein refers to a group in which one or more substituents of an alkyl group are substituted with a halogen, and examples thereof may include CF₃ and the like. Here, the halogen may be F, Cl, Br, or I.

The term “alkoxy group” as used herein refers to a monovalent group represented by —OA₁₀₁, wherein A₁₀₁ is an alkyl group. Examples of the alkoxy group may include a methoxy group, an ethoxy group, an isopropyloxy group, and the like.

The term “alkylthio group” as used herein refers to a monovalent group represented by —SA₁₀₁, wherein A₁₀₁ is an alkyl group.

The term “halogenated alkyl group” as used herein refers to a group in which one or more hydrogen atoms of an alkoxy group are substituted with a halogen, and examples thereof may include —OCF₃ and the like.

The term “halogenated alkylthio group” as used herein refers to a group in which one or more hydrogen atoms of an alkylthio group are substituted with a halogen, and examples thereof may include —SCF₃ and the like.

The term “cycloalkyl group” as used herein refers to a monovalent saturated hydrocarbon cyclic group, and examples thereof may include monocyclic groups such as a cyclopropyl group, a cyclobutyl group, a cyclopentyl group, a cyclohexyl group, a cycloheptyl group, and the like, and polycyclic condensed cyclic groups such as a norbornyl group and an adamantyl group. The term “cycloalkylene group” as used herein refers to a divalent saturated hydrocarbon cyclic group, and examples thereof may include a cyclopentylene group, a cyclohexylene group, an adamantylene group, an adamantylmethylene group, a norbornylene group, a norbornylmethylene group, a tricyclodecanylene group, a tetracyclododecanylene group, a tetracyclododecanylmethylene group, a dicyclohexylmethylene group, and the like.

The term “cycloalkoxy group” as used herein refers to a monovalent group represented by —OA₁₀₂, where A₁₀₂ is a cycloalkyl group. Examples of the cycloalkoxy group may include a cyclopropoxy group, a cyclobutoxy group, and the like.

The term “cycloalkylthio group” as used herein refers to a monovalent group represented by —SA₁₀₂, wherein A₁₀₂ is a cycloalkyl group.

The term “heterocycloalkyl group” as used herein refers to a group in which some carbon atoms of the cycloalkyl group are replaced by a moiety including a heteroatom, such as oxygen, sulfur, or nitrogen, and the heterocycloalkyl group may specifically include an ether bond, an ester bond, a sulfonate ester bond, carbonate, a lactone ring, a sultone ring, or a carboxylic anhydride moiety. The term “heterocycloalkylene group” as used herein refers to a group in which some carbon atoms of the cycloalkylene group are replaced by a moiety including a heteroatom, such as oxygen, sulfur, or nitrogen.

The term “heterocycloalkoxy group” as used herein refers to a monovalent group represented by —OA₁₀₃, wherein A₁₀₃ is a heterocycloalkyl group.

The term “heterocycloalkylthio group” as used herein refers to a monovalent group represented by —SA₁₀₃, wherein A₁₀₃ is a heterocycloalkyl group.

The term “alkenyl group” as used herein refers to a linear or branched unsaturated aliphatic monovalent hydrocarbon including one or more carbon-carbon double bond. The term “alkenylene group” as used herein refers to a linear or branched unsaturated aliphatic divalent hydrocarbon including one or more carbon-carbon double bonds.

The term “cycloalkenyl group” as used herein refers to a monovalent unsaturated cyclic hydrocarbon group including one or more carbon-carbon double bonds. The term “cycloalkenylene group” as used herein refers to a divalent unsaturated cyclic hydrocarbon group including one or more carbon-carbon double bonds.

The term “heterocycloalkenyl group” as used herein refers to a group in which some carbon atoms of the cycloalkenylene group are replaced by a moiety including a heteroatom, such as oxygen, sulfur, or nitrogen. The term “heterocycloalkenylene group” as used herein refers to a group in which some carbon atoms of the cycloalkenylene group are replaced by a moiety including a heteroatom, such as oxygen, sulfur, or nitrogen.

The term “alkynyl group” as used herein refers to a linear or branched unsaturated aliphatic monovalent hydrocarbon including one or more carbon-carbon triple bonds.

The term “aryl group” as used herein refers to a monovalent group having a carbocyclic aromatic system, and examples thereof may include a phenyl group, a naphthyl group, an anthracenyl group, a phenanthrenyl group, a pyrenyl group, a chrysenyl group, and the like. The term “arylene group” as used herein refers to a divalent group having a carbocyclic aromatic system.

The term “aryloxy group” as used herein refers to a monovalent group represented by —OA₁₀₄, wherein A₁₀₄ is an aryl group.

The term “arylthio group” as used herein refers to a monovalent group represented by —SA₁₀₄, wherein A₁₀₄ is an aryl group.

The term “heteroaryl group” as used herein refers to a monovalent group having a heterocyclic aromatic system, and examples thereof may include a pyridinyl group, a pyrimidinyl group, a pyrazinyl group, and the like. The term “heteroarylene group” as used herein refers to a divalent group having a heterocyclic aromatic system.

The term “heteroaryloxy group” as used herein refers to a monovalent group represented by —OA₁₀₅, wherein A₁₀₅ is a heteroaryl group.

The term “heteroarylthio group” as used herein refers to a monovalent group represented by —SA₁₀₅, wherein A₁₀₅ is a heteroaryl group.

The term “arylalkyl group” as used herein refers to a monovalent group in which a carbocyclic aromatic system is substituted on an alkyl group, and specific examples thereof may include a benzyl group, a diphenylmethyl group, and the like.

The term “heteroarylalkyl group” as used herein refers to a monovalent group in which a carbocyclic aromatic system is substituted on an alkyl group.

The term “heterocyclic group” as used herein refers to a C1-C6 monocyclic or polycyclic group including at least one heteroatom, and is a group including all of a monovalent group, a divalent group, a trivalent group, and the like.

The term “substituent” as used herein may include: deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₅-C₂₀ cycloalkyl group, a C₃-C₂₀ cycloalkoxy group, a C₅-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, or a C₁-C₂₀ heteroarylthio group;

a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, and a C₁-C₂₀ heteroarylthio group, each substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₆-C₂₀ aryloxy group, a C₆-C₂₀ arylthio group, a C₁-C₂₀ heteroaryl group, a C₁-C₂₀ heteroaryloxy group, a C₁-C₂₀ heteroarylthio group, and any combination thereof; and any combination thereof.

Hereinafter, an embodiment according to the disclosure will be described in detail with reference to the drawings, and in the description with reference to the drawings, the same or substantially the same or corresponding elements are denoted with the same reference numerals, and overlapping descriptions thereof will be omitted. Regarding the drawings, the thickness is shown enlarged to clearly express the various layers and regions. Also, in the drawings, the thicknesses of some layers and regions are exaggerated for convenience of description. On the other hand, the embodiments described below are merely illustrative, and various modifications can be made on these embodiments.

### [Resist Composition]

A resist composition according to embodiments may include: an organometallic compound represented by Formula 1; and
a polymer including a first repeating unit represented by Formula 2 and a second repeating unit represented by Formula 3:

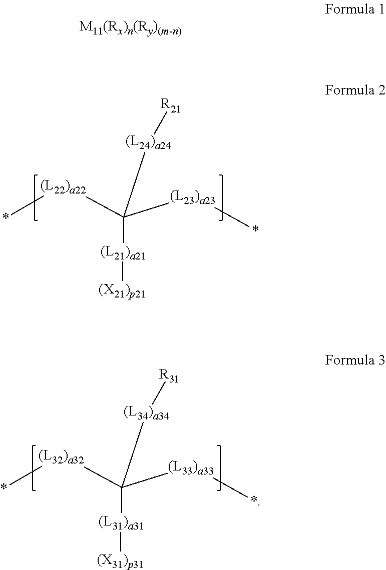

In Formulae 1 to 3,
M₁₁ may be indium (In), tin (Sn), antimony (Sb), tellurium (Te), thallium (Tl), lead (Pb), bismuth (Bi), or polonium (Po),
Rₓ may be *-(L₁)ₐ₁-(R₁)_{b1},
R_{y} may be *—Y₁—X₁,
n may be an integer from 1 to 6,
m may be an integer from 0 to 6,
m−n may be greater than or equal to 0,
a plurality of Rₓ may be identical or different from each other,
a plurality of R_{y} may be identical or different from each other,
L₁ may be a single bond or a linear, branched, or cyclic C₁-C₃₀ divalent hydrocarbon group,
a1 may be an integer from 1 to 4,
R₁ may be a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group, wherein two adjacent groups among a plurality of R₁ may be optionally bound together to form a condensed ring,
b1 may be an integer from 1 to 4,
Y₁ may be O, O(C═O), S, S(C═O), NX₁₄, or N(C═O),
X₁ and X₁₄ may each independently be hydrogen, deuterium, or a linear, branched, or cyclic C₁-C₃₀ monovalent hydrocarbon group that optionally includes a heteroatom,
L₂₁ to L₂₃ may each independently be a single bond, O, S, C(═O), C(═O)O, OC(═O), C(═O)NR₂₂, NR₂₂C(═O), S(═O), S(═O)₂, S(═O)₂O, OS(═O)₂, or a linear, branched, or cyclic C₁-C₃₀ divalent hydrocarbon group that optionally includes a heteroatom,
L₃₁ to L₃₃ may each independently be a single bond, O, S, C(═O), C(═O)O, OC(═O), C(═O)NR₂₂, NR₂₂C(═O), S(═O), S(═O)₂, S(═O)₂O, OS(═O)₂, or a linear, branched, or cyclic C₁-C₃₀ divalent hydrocarbon group that optionally includes a heteroatom,
L₂₄ may be C(═O)O, OC(═O), C(═O)S, SC(═O), OC(═O)O, SC(═O)O, OC(═O)S, SC(═O)S, C(═O)NR₂₂, NR₂₂C(═O), OC(═O)NR₂₂, or NR₂₂C(═O)O,
L₃₄ may be C(═O)O, OC(═O), C(═O)S, SC(═O), OC(═O)O, SC(═O)O, OC(═O)S, SC(═O)S, C(═O)NR₃₂, NR₃₂C(═O), OC(═O)NR₃₂, or NR₃₂C(═O)O,
a21 to a24 and a31 to a34 may each independently be an integer from 1 to 4,
R₂₁, R₂₂, R₃₁, and R₃₂ may each independently be hydrogen, deuterium, or a linear, branched, or cyclic C₁-C₃₀ monovalent hydrocarbon group that optionally includes a heteroatom,
X₂₁ may be a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
X₃₁ may be an electron-withdrawing group,
p21 and p31 may each independently be an integer from 1 to 5, and
* indicates a binding site to a neighboring atom.

In Formula 1, a bond between M₁₁ and Rₓ may be a M₁₁-carbon single bond, and a bond between M₁₁ and R_{y} may be a M₁₁-oxygen single bond, a M₁₁-sulfur single bond, or a M₁₁-nitrogen single bond.

In Formula 1, a bond between M₁₁ and Rₓ may be a M₁₁-carbon single bond, and a bond between M₁₁ and R_{y} may be a M₁₁-oxygen single bond.

A molecular weight of the organometallic compound may be about 3,000 g/mol or less. For example, the molecular weight of the organometallic compound may be about 2,000 g/mol or less.

Although not limited to a particular theory, the organometallic compound may form radicals by heat and/or high-energy rays. Radicals may be formed from the M₁₁-carbon bond of the organometallic compound, or optionally, in an atmosphere where water is present, radicals may react to form chemical bonds between the organometallic compound. Accordingly, the physical properties, particularly solubility in a developer, of the organometallic compound may change.

A (calculated) bond dissociation energy value of the bond between M₁₁ and Rₓ in the organometallic compound may be 30 kcal/mol or less. Although not limited to a particular theory, Rₓ may include a double bond or a triple bond, which may accordingly stabilize radicals formed when the bond between Rₓ and M₁₁ is decomposed. In this regard, the bond dissociation energy value of the bond between M₁₁ and Rₓ in the organometallic compound may be lowered.

That is, since the organometallic compound has a ligand with a specific structure, the organometallic compound may have improved photosensitivity, stability, and/or coating properties.

For example, in Formula 1, M₁₁ may be In, Sn, or Sb. In some embodiments, in Formula 1, M₁₁ may be Sn.

In Formula 1, m refers to a valency of M₁₁.

For example, in Formula 1, n may be an integer from 1 to 4.

For example, in Formula 1, m may be an integer from 0 to 4.

In an embodiment, in Formula 1, n may be an integer from 1 to 4, m may be an integer from 0 to 4, and M₁₁ may be Sn.

In an embodiment, L₁ in Formula 1 may be a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C6-C30 arylene group, or a substituted or unsubstituted C1-C30 heteroarylene group.

In some embodiments, L₁ in Formula 1 may be selected from: a single bond; and a C₁-C₃₀ alkylene group, a C₃-C₃₀ cycloalkylene group, a C₃-C₃₀ heterocycloalkylene group, a C₂-C₃₀ alkenylene group, a C₃-C₃₀ cycloalkenylene group, a C₃-C₃₀ heterocycloalkenylene group, a C₆-C₃₀ arylene group, and a C₁-C₃₀ heteroarylene group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In some embodiments, L₁ in Formula 1 may be selected from: a single bond; and a C₁-C₃₀ alkylene group unsubstituted or substituted with deuterium, a halogen, a hydroxyl group, a cyano group, a C₁-C₂₀ alkyl group, a C₁-C₂₀ halogenated alkyl group, or any combination thereof.

For example, in Formula 1, a1 may be 1 or 2.

For example, R₁ in Formula 1 may be selected from a C₁-C₃₀ alkyl group, a C₃-C₃₀ cycloalkyl group, a C₅-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In some embodiments, R₁ in Formula 1 may be selected from a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₅-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

In some embodiments, R₁ in Formula 1 may be any one selected from Formulae 4-1 to 4-21:

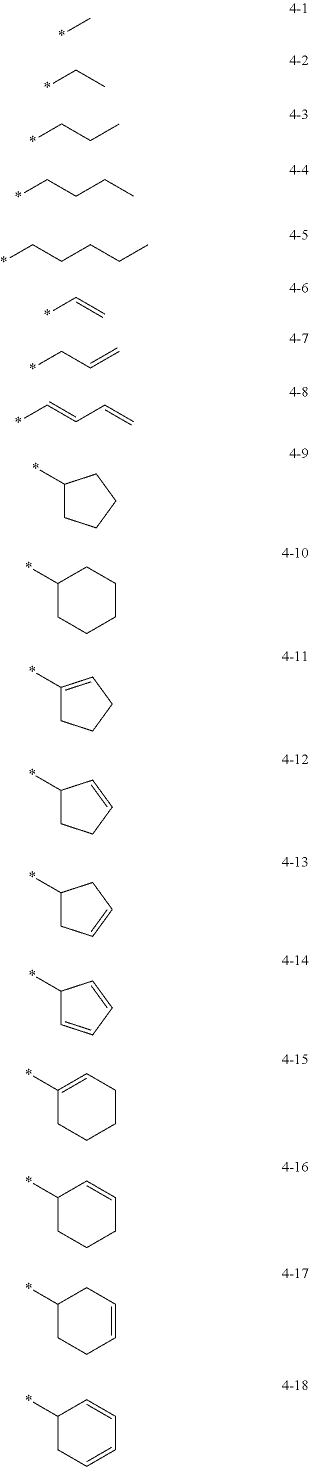

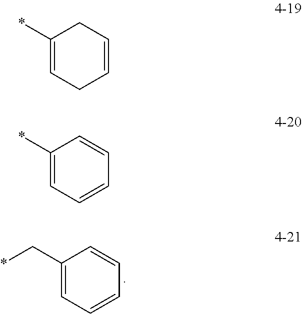

wherein, in Formulae 4-1 to 4-21,
at least one hydrogen atom may optionally be substituted with deuterium, a halogen, a cyano group, a nitro group, a hydroxyl group, a thiol group, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, or any combination thereof.

In Formula 1, b1 indicates the number of substituents of R₁, and for example, b1 in Formula 1 may be 1 or 2.

For example, Y₁ in Formula 1 may be O, O(C═O), S, or S(C═O).

For example, in Formula 1, X₁ and X₁₄ may each independently be selected from: hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₅-C₃₀ cycloalkyl group, a C₃-C₃₀ cycloalkoxy group, a C₃-C₃₀ cycloalkylthio group, a C₃-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₅-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy, a C₁-C₂₀ heteroarylthio group, or any combination thereof.

In some embodiments, in Formula 1, X₁ and X₁₄ may each independently be selected from: hydrogen; deuterium; and a C₁-C₃₀ alkyl group, a C₁-C₃₀ halogenated alkyl group, a C₅-C₃₀ cycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a C₁-C₂₀ alkyl group, a C₁-C₂₀ halogenated alkyl group, a C₃-C₂₀ cycloalkyl group, a C₆-C₂₀ aryl group, or any combination thereof.

In some embodiments, in Formula 1, X₁ and X₁₄ may each independently be selected from: hydrogen; deuterium; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, and a C₆-C₃₀ aryl group, each unsubstituted or substituted with deuterium, a halogen, or any combination thereof.

In particular, in Formula 1, X₁ and X₁₄ may each independently be selected from: hydrogen; deuterium; and a methyl group, an ethyl group, an n-propyl group, an iso-propyl group, an n-butyl group, a sec-butyl group, an iso-butyl group, a tert-butyl group, a cyclopentyl group, a cyclohexyl group, an ethenyl group, a cyclopentenyl group, a cyclopentadienyl group, a cyclohexenyl group, a cyclohexadienyl group, an ethynyl group, a phenyl group, and a naphthyl group, each unsubstituted or substituted with deuterium, a halogen, a methyl group, an ethyl group, a phenyl group, a naphthyl group, or any combination thereof.

In an embodiment, the organometallic compound may be represented by one of Formulae 1-1 to 1-4:

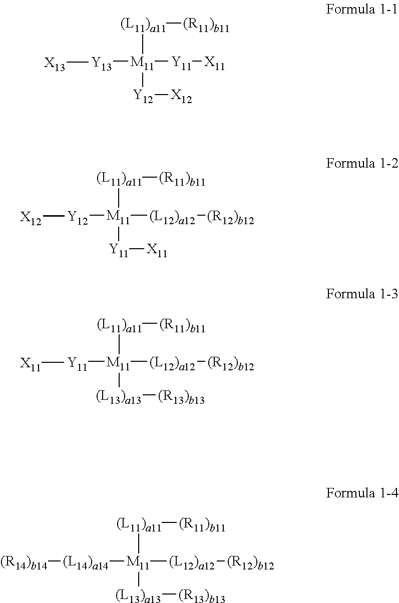

wherein, in Formulae 1-1 to 1-4,
M₁₁ is the same as defined in Formula 1,
L₁₁ to L₁₄ are each independently the same as described in connection with L₁ in Formula 1,
a11 to a14 are each independently the same as described in connection with a1 in Formula 1,
R₁₁ to R₁₄ are each independently the same as described in connection with R₁ in Formula 1,
b11 to b14 are each independently the same as described in connection with b1 in Formula 1,
Y₁₁ to Y₁₃ are each independently the same as described in connection with Y₁ in Formula 1, and
X₁₁ to X₁₃ are each independently the same as described in connection with X₁ in Formula 1.

In one or more embodiments, the organometallic compound may be represented by one of Formulae 1-1 to 1-3:

In one or more embodiments, the organometallic compound represented by Formula 1 may be selected from Group I:

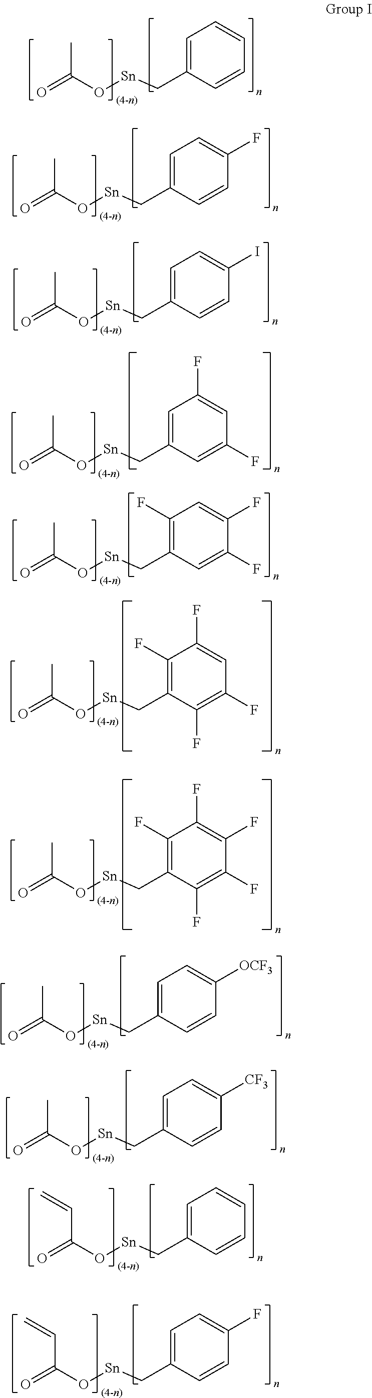

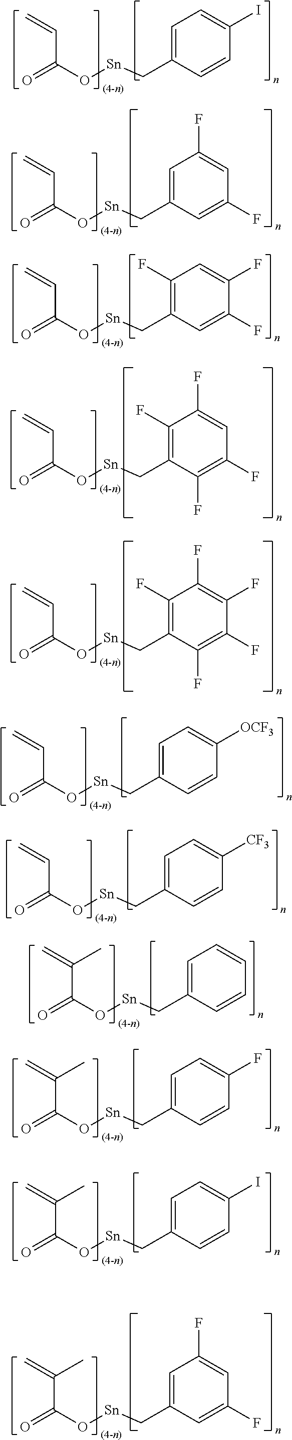

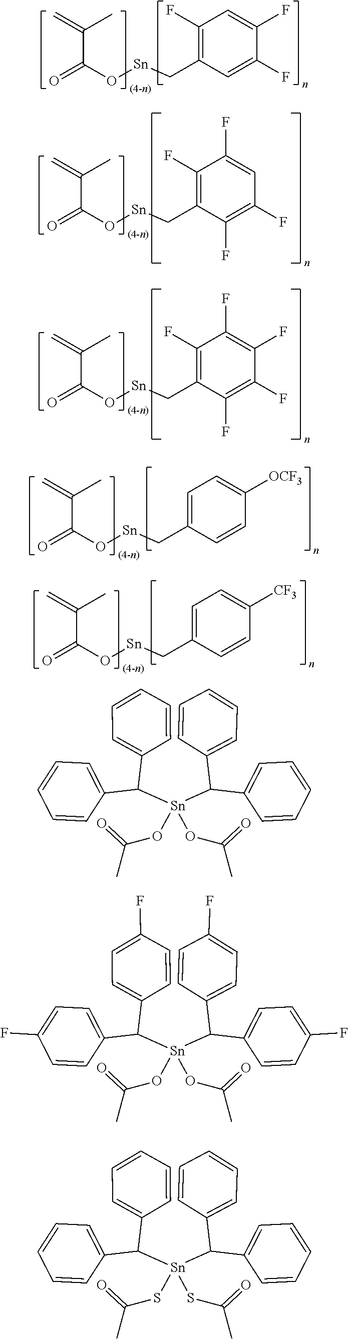

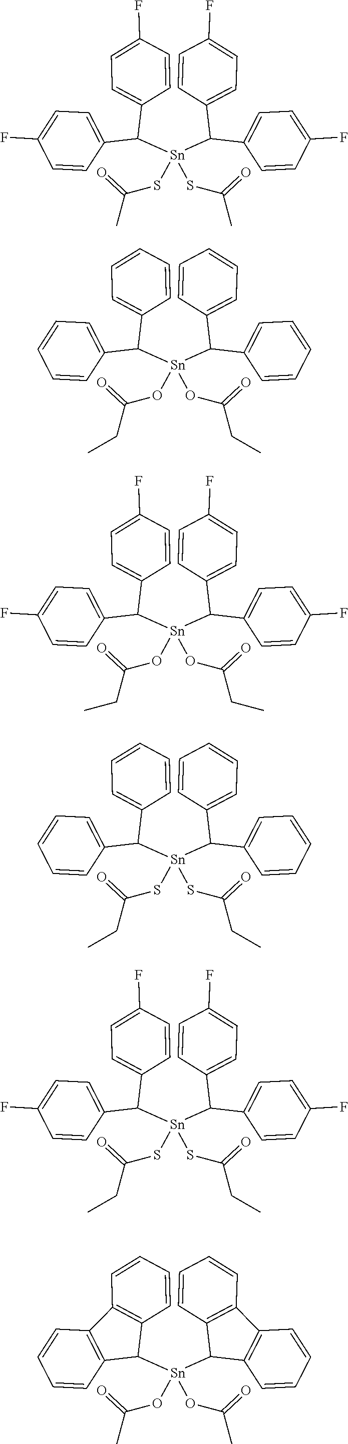

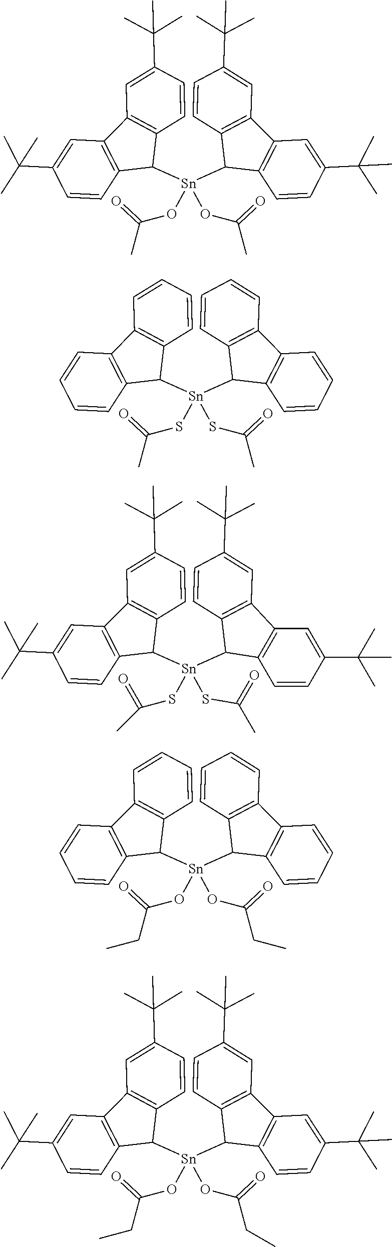

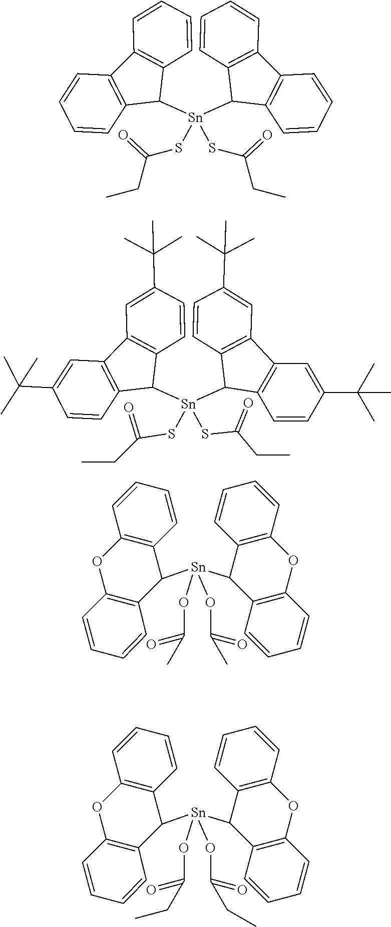

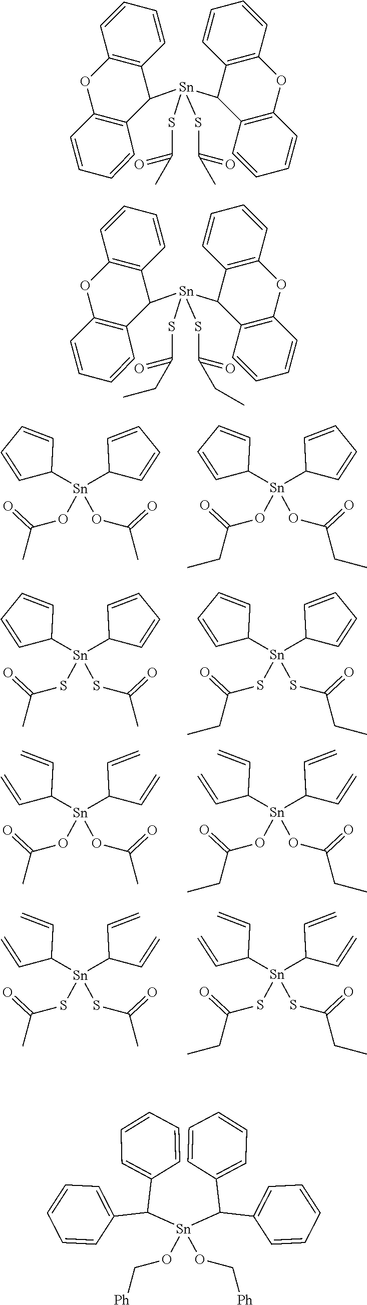

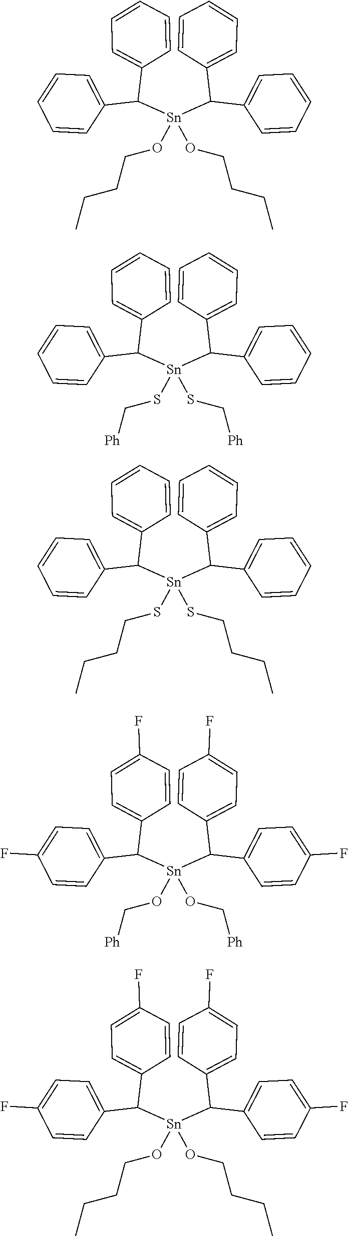

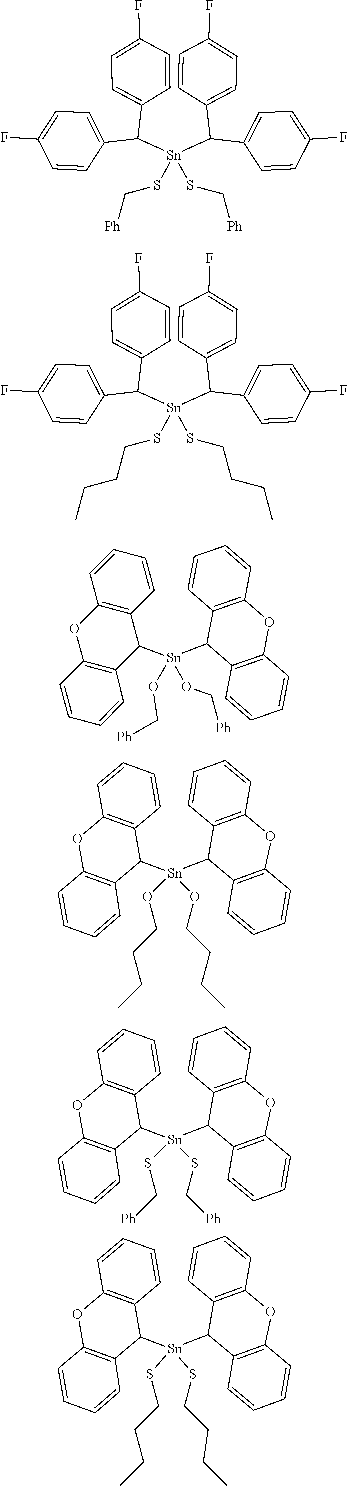

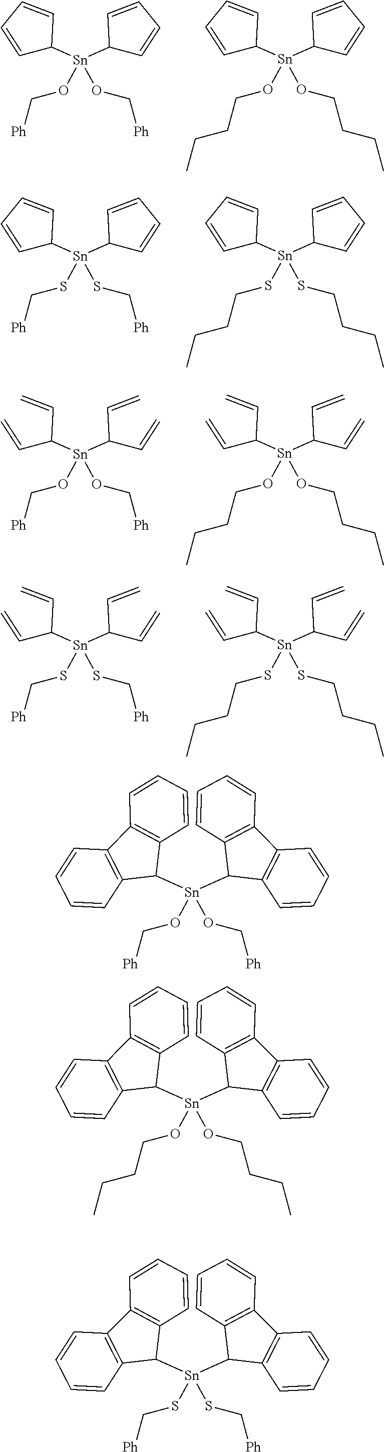

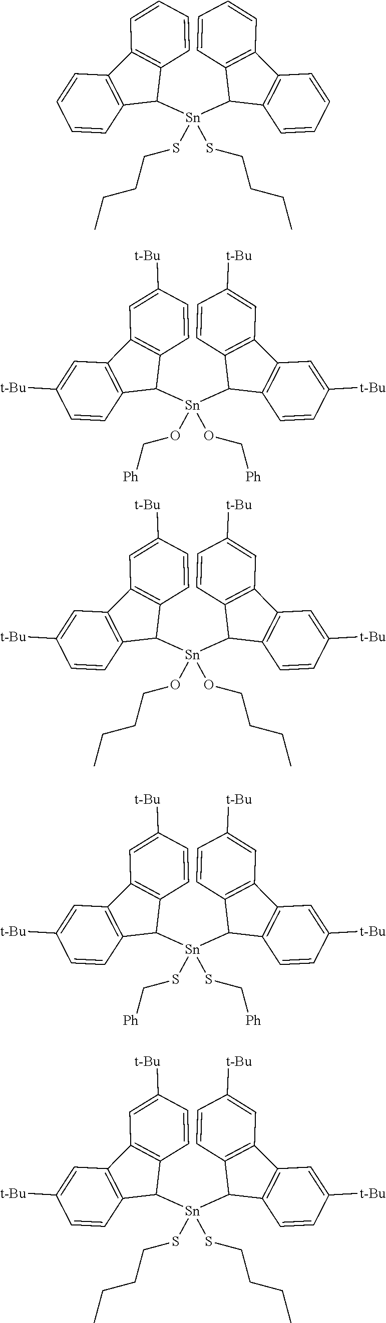

wherein, in Group I, n may be an integer from 1 to 4.

For example, in Formulae 2 and 3, L₂₁ to L₂₃ and L₃₁ to L₃₃ may each independently be a single bond, O, S, C(═O), C(═O)O, OC(═O), C(═O)NH, NHC(═O), S(═O), S(═O)₂, S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group.

In some embodiments, in Formulae 2 and 3, L₂₁ to L₂₃ and L₃₁ to L₃₃ may each independently be selected from: a single bond; O; C(═O); C(═O)O; OC(═O); C(═O)NH; NHC(═O); and a C₁-C₂₀ alkylene group, a C₃-C₂₀ cycloalkylene group, a C₅-C₂₀ heterocycloalkylene group, a C₂-C₂₀ alkenylene group, a C₃-C₂₀ cycloalkenylene group, a C₃-C₂₀ heterocycloalkenylene group, a C₆-C₂₀ arylene group, and a C₁-C₂₀ heteroarylene group, each unsubstituted or substituted with deuterium, a halogen, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₃-C₂₀ cycloalkoxy group, a C₆-C₂₀ aryl group, or any combination thereof.

In some embodiments, in Formulae 2 and 3, L₂₁ to L₂₃ and L₃₁ to L₃₃ may each independently be selected from: a single bond; O; C(═O); C(═O)O; OC(═O); C(═O)NH; NHC(═O); and a C₁-C₂₀ alkylene group, a C₅-C₂₀ cycloalkylene group, a C₃-C₂₀ heterocycloalkylene group, a phenylene group, and a naphthylene group, each unsubstituted or substituted with deuterium, a halogen, a C₁-C₂₀ alkyl group, a C₁-C₂₀ halogenated alkyl group, a C₁-C₂₀ alkoxy group, a phenyl group, a naphthyl group, or any combination thereof.

For example, in Formulae 2 and 3, L₂₄ and L₃₄ may each independently be C(═O)O, OC(═O), C(═O)S, SC(═O), C(═O)NH, C(═O)NCH₃, NHC(═O), or NCH₃C(═O).

In Formulae 2 and 3, a21 to a24 and a31 to a34 indicate the number of repetitions of L₂₁ to L₂₄ and L₃₁ to L₃₄, respectively, and for example, may be an integer from 1 to 3. In some embodiments, in Formulae 2 and 3, a21 to a24 and a31 to a34 may each independently be 1.

For example, in Formulae 2 and 3, R₂₁, R₂₂, R₃₁, and R₃₂ may each independently be selected from: hydrogen; deuterium; and a C₁-C₂₀ alkyl group, a C₃-C₂₀ cycloalkyl group, and a C₆-C₂₀ aryl group, each unsubstituted or substituted with deuterium, a halogen, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₅-C₂₀ cycloalkoxy group, a C₆-C₂₀ aryl group, or any combination thereof.

In some embodiments, in Formulae 2 and 3, R₂₁, R₂₂, R₃₁, and R₃₂ may each independently be selected from: hydrogen; deuterium; and a C₁-C₂₀ alkyl group and a C₆-C₂₀ aryl group, each unsubstituted or substituted with deuterium, a halogen, a cyano group, a C₁-C₂₀ alkyl group, a C₆-C₂₀ aryl group, or any combination thereof.

In some embodiments, in Formulae 2 and 3, R₂₁, R₂₂, R₃₁, and R₃₂ may each independently be H, D, F, Cl, CH₃, C₂H₅, C₃H₇, C₄H₉, CH(CH₃)₂, C(CH₃)₃, CH₂C(CH₃)₃, CH₂F, CHF₂, CF₃, CHFCH₃, CHFCH₂F, CHFCHF₂, CHFCF₃, CH₂CF₃, CF₂CH₃, CF₂CH₂F, CF₂CHF₂, CF₂CF₃, CH₂Cl, CHCl₂, CCl₃, CHClCH₃, CHClCH₂Cl, CHClCHCl₂, CHClCCl₃, CH₂CCl₃, CCl₂CH₃, CCl₂CH₂Cl, CCl₂CHCl₂, CCl₂CCl₃, C₆H₆, C₆F₆, C₆Cl₆, CH₂C₆H₆, CH₂C₆F₆, or CH₂C₆Cl₆.

For example, in Formula 2, X₂₁ may be selected from a C₂-C₂₀ alkenyl group, a C₃-C₂₀ cycloalkenyl group, a C₂-C₂₀ alkynyl group, and a C₆-C₂₀ aryl group, each unsubstituted or substituted with deuterium, a halogen, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₅-C₂₀ cycloalkoxy group, a C₆-C₂₀ aryl group, or any combination thereof.

In some embodiments, in Formula 2, X₂₁ may be selected from a C₆-C₂₀ aryl group unsubstituted or substituted with deuterium, a halogen, a cyano group, a hydroxyl group, an amino group, a carboxylate group, a thiol group, a C₁-C₂₀ alkyl group, a C₁-C₂₀ halogenated alkyl group, a C₁-C₂₀ alkoxy group, a C₅-C₂₀ cycloalkyl group, a C₃-C₂₀ cycloalkoxy group, a C₆-C₂₀ aryl group, or any combination thereof.

For example, in Formula 3, X₃₁ may be selected from: a halogen; a cyano group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group a C₆-C₃₀ aryl group, and a C₇-C₃₀ arylalkyl group, each unsubstituted or substituted with a halogen, a cyano group, a C₁-C₂₀ halogenated alkyl group, or any combination thereof.

In some embodiments, in Formula 3, X₃₁ may be selected from: a halogen; a cyano group; and a C₁-C₂₀ alkyl group and a C₆-C₂₀ aryl group, each unsubstituted or substituted with a halogen, a cyano group, a C₁-C₂₀ halogenated alkyl group, or any combination thereof.

In some embodiments, in Formula 3, X₃₁ may be F, CH₂F, CHF₂, CF₃, CHFCH₃, CHFCH₂F, CHFCHF₂, CHFCF₃, CH₂CF₃, CF₂CH₃, CF₂CH₂F, CF₂CHF₂, CF₂CF₃, Cl, CH₂Cl, CHCl₂, CCl₃, CHClCH₃, CHClCH₂Cl, CHClCHCl₂, CHClCCl₃, CH₂CCl₃, CCl₂CH₃, CCl₂CH₂Cl, CCl₂CHCl₂, CCl₂CCl₃, C₆F₆, or C₆Cl₆.

In an embodiment, the first repeating unit may be selected from Group II:

In an embodiment, the second repeating unit may be selected from Group III:

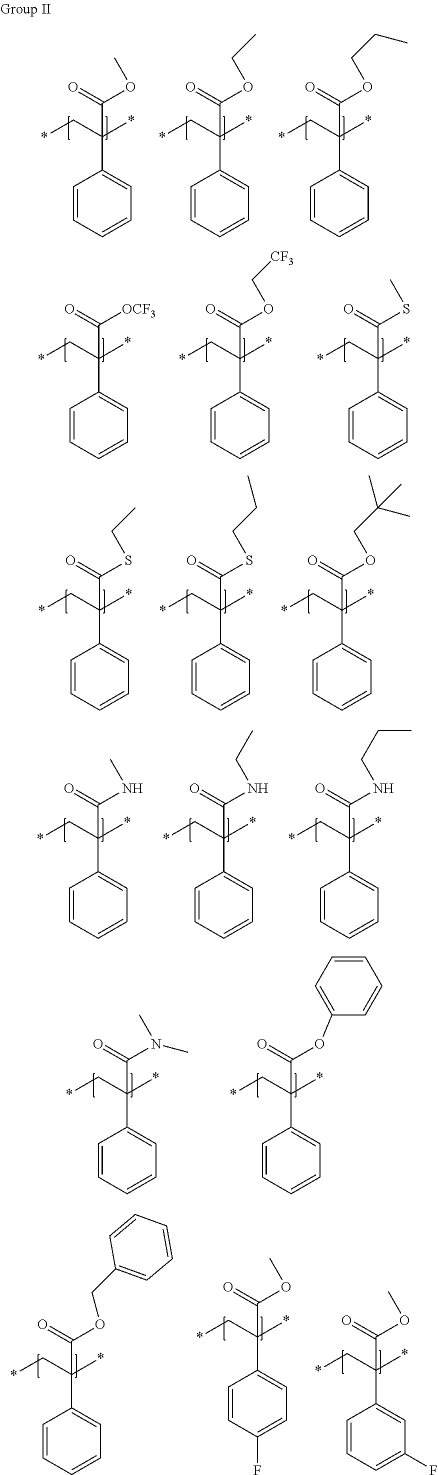

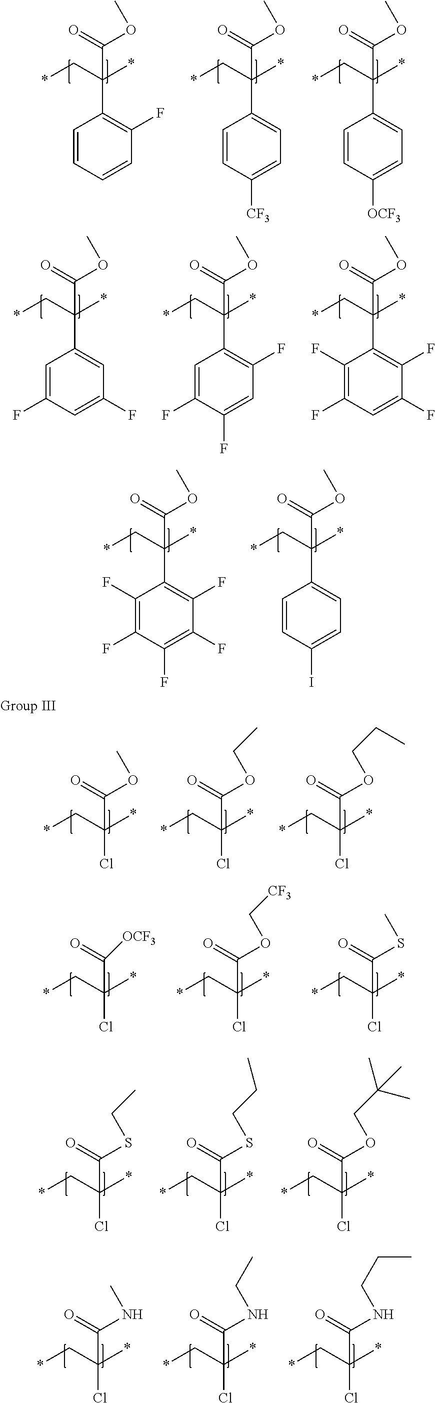

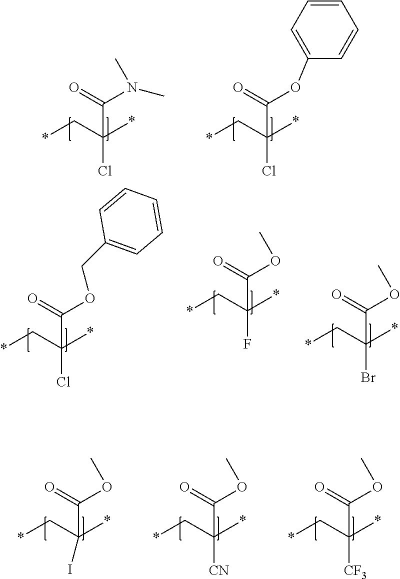

wherein, in Group II and Group III, * indicates a binding site to a neighboring atom.

The polymer may form cross-links by a reaction with radicals formed from the organometallic compound. Therefore, the resist composition including the polymer may have improved photosensitivity, stability, and/or coating properties, compared to a resist composition not including the polymer.

In particular, the resist composition including the polymer may have a suitable expiration date for commercial distribution.

Any one type of the organometallic compound may be used, or a combination of two or more types of the organometallic compound may be used.

Likewise, any one type of the polymer represented by Formula 2 may be used, or a combination of two or more types of the polymer may be used.

In the resist composition, a weight of the organometallic compound may be, based on 100 parts by weight of the resist composition, in a range of about 0.01 parts by weight to about 100 parts by weight, and may be about 0.2 parts by weight or more, about 0.5 parts by weight or more, about 1 part by weight or more, about 1.5 parts by weight or more, about 90 parts by weight or less, or about 80 parts by weight or less. When the weight is satisfied within the ranges above, side reactions may be limited and/or suppressed while sufficiently forming chemical bonds between the organometallic compound so that the resist composition having improved sensitivity and/or resolution may be provided.

In the resist composition, a weight of the polymer may be, based on 100 parts by weight of the resist composition, in a range of about 0.01 parts by weight to about 100 parts by weight, and may be about 0.2 parts by weight or more, about 0.5 parts by weight or more, about 1 part by weight or more, about 1.5 parts by weight or more, about 90 parts by weight or less, or about 80 parts by weight or less. When the weight is satisfied within the ranges above, side reactions may be suppressed while sufficiently forming chemical bonds between the organometallic compound so that the resist composition having improved sensitivity and/or resolution may be provided, and the solubility of the organometallic compound may be improved.

In the resist composition, the amount of the polymer may be, based on 100 parts by weight of the organometallic compound, in a range of about 0.1 parts by weight to about 100,000 parts by weight. In an embodiment, in the resist composition, the weight of the organometallic compound may be greater than or equal to the weight of the polymer. A ratio of the weight of the organometallic compound to the weight of the polymer may be in a range of about 9:1 to about 5:5, such as 9:1, 8:2, or 7:3, but not limited thereto. When the ratio is satisfied within the ranges above, the photosensitivity, stability, and/or coating properties of the resist composition may be improved.

The solubility of the resist composition in a developer may be changed upon exposure to high-energy rays. The resist composition may be a positive-type resist composition in which a positive resist pattern is formed by dissolving and removing an exposed region of the resist film.

In addition, the resist composition according to an embodiment may be used for an alkali developing process using an alkali developer for a developing process in forming a resist pattern, or may be used for a solvent developing process using a developer containing an organic solvent for the developing process (hereinafter also referred to as an organic developer).

Since the resist composition is a non-chemically amplified type, the resist composition substantially may not include a photoacid generator.

Since the properties of the organometallic compound change upon exposure, the resist composition substantially may not include a compound having a molecular weight of about 1,000 or more, in addition to the organometallic compound and the polymer.

The organometallic compound and the polymer may be prepared by any suitable method, or commercially available products may be used.

The structure (composition) of the organometallic compound may be confirmed by performing FT-IR analysis, NMR analysis, X-ray fluorescence (XRF) analysis, mass spectrometry, UV analysis, single crystal X-ray structure analysis, powder X-ray diffraction (PXRD) analysis, liquid chromatography (LC) analysis, size exclusion chromatography (SEC) analysis, thermal analysis, and the like. Details on such confirmation methods are the same as described in Examples below.

### <Organic Solvent>

The resist composition may further include an organic solvent.

The organic solvent included in the resist composition may not be particularly limited as long as it is capable of dissolving or dispersing the organometallic compound, an additive, and optional components contained as necessary. One type of the organic solvent may be used, or two or more different types of the organic solvent may be used in combination.

Since the resist composition substantially may not include water, the organic solvent may not include water. In some embodiments, the resist composition may include 3 weight % or less of water, and the organic solvent may include 3 weight % or less of water.

Examples of the organic solvent may include an alcohol-based solvent, an ether-based solvent, a ketone-based solvent, an amide-based solvent, an ester-based solvent, a sulfoxide-based solvent, a hydrocarbon-based solvent, and the like.

Examples of the alcohol-based solvent may include: a monoalcohol-based solvent, such as methanol, ethanol, n-propanol, isopropanol, 1-methoxy-2-propanol, 1-ethoxy-2-propanol, n-butanol, isobutanol, sec-butanol, tert-butanol, n-pentanol, isopentanol, 2-methylbutanol, sec-pentanol, tert-pentanol, 3-methoxybutanol, 3-methyl-3-methoxybutanol, n-hexanol, 2-methylpentanol, sec-hexanol, 2-ethylbutanol, 4-methyl-2-pentanol (MIBC), sec-heptanol, 3-heptanol, n-octanol, 2-ethylhexanol, sec-octanol, n-nonylalcohol, 2,6-dimethyl-4-heptanol, n-decanol, sec-undecyl alcohol, trimethylnonyl alcohol, sec-tetradecyl alcohol, sec-heptadecyl alcohol, furfuryl alcohol, phenol, cyclohexanol, methylcyclohexane alcohol, 3,3,5-trimethylcyclohexanol, benzyl alcohol, diacetone alcohol, and the like; a polyhydric alcohol solvent, such as ethylene glycol, 1,2-propylene glycol, 1,3-butylene glycol, 2,4-pentanediol, 2-methyl-2,4-pentanediol, 2,5-hexanediol, 2,4-heptanediol, 2-ethyl-1,3-hexanediol, diethylene glycol, dipropylene glycol, triethylene glycol, and tripropylene glycol; and polyhydric alcohol-containing ether solvents such as ethylene glycol monomethyl ether, ethylene glycol monoethyl ether, ethylene glycol monopropyl ether, ethylene glycol monobutyl ether, ethylene glycol monohexyl ether, ethylene glycol monophenyl ether, ethylene glycol mono-2-ethylbutyl ether, diethylene glycol monomethyl ether, diethylene glycol monoethyl ether, diethylene glycol monopropyl ether, diethylene glycol monobutyl ether, diethylene glycol monohexyl ether, propylene glycol monomethyl ether, propylene glycol monoethyl ether, propylene glycol monopropyl ether, propylene glycol monobutyl ether, dipropylene glycol monomethyl ether, dipropylene glycol monoethyl ether, dipropylene glycol monopropyl ether, and the like.

Examples of the ether-based solvent may include: a dialkylether-based solvent, such as diethylether, dipropylether, dibutylether, diethylene glycol dimethylether, dipropyleneglycol dimethylether, and the like; a cyclic ether-based solvent, such as tetrahydrofuran, tetrahydropyran, and the like; and an aromatic ring-containing ether-based solvent, such as diphenylether, anisole, and the like.

Examples of the ketone solvents may include: a chain ketone solvent, such as acetone, methylethylketone, methyl-n-propyl ketone, methyl-n-butyl ketone, methyl-n-pentyl ketone, diethyl ketone, methyl isobutyl ketone, 2-heptanone, ethyl-n-butyl ketone, methyl-n-hexy ketone, diisobutyl ketone, and trimethyl nonanone; a cyclic ketone solvent, such as cyclopentanone, cyclohexanone, cycloheptanone, cyclooctanone, and methylcyclohexanone; 2,4-pentandione, acetonyl acetone, acetphenonem, and the like.

Examples of the amide solvent may include: a cyclic amide solvent, such as N,N′;-dimethylimidazolidinone and N-methyl-2-pyrrolidone; and a chain amide solvent, such as N-methylformamide, N,N-dimethylformamide, N,N-diethylformamide, acetamide, N-methylacetamide, N,N-dimethylacetamide, N-methylpropionamide, and the like.

Examples of the ester solvent may include: an acetate ester solvent, such as methyl acetate, ethyl acetate, n-propyl acetate, isopropyl acetate, n-butyl acetate, isobutyl acetate, sec-butyl acetate, T-butyl acetate, n-pentyl acetate, isopentyl acetate, sec-pentyl acetate, 3-methoxybutyl acetate, methylpentyl acetate, 2-ethylbutyl acetate, 2-ethylhexyl acetate, benzyl acetate, cyclohexyl acetate, methylcyclohexyl acetate, n-nonyl acetate, and the like; a polyhydric alcohol-containing ether carboxylate solvent, such as ethylene glycol monomethyl ether acetate, ethylene glycol monoethyl ether acetate, diethylene glycol monomethyl ether acetate, diethylene glycol monoethyl ether acetate, diethylene glycol mono-n-butyl ether acetate, propylene glycol monomethyl ether acetate, propylene glycol monoethyl ether acetate, propylene glycol monopropyl ether acetate, propylene glycol monobutyl ether acetate, dipropylene glycol monomethyl ether acetate, dipropylene glycol monoethyl ether acetate, and the like; a lactone solvent, such as γ-butyrolactone and δ-valerolactone; carbonate solvents such as dimethyl carbonate, diethyl carbonate, ethylene carbonate, and propylene carbonate; lactate ester solvents such as methyl lactate, ethyl lactate, n-butyl lactate, n-amyl lactate, and the like; glycoldiacetate; methoxytriglycol acetate; ethyl propionate; n-butyl propionate; isoamyl propionate; diethyloxalate; di-n-butyloxalate; methyl acetoacetate; ethyl acetoacetate; diethyl malonate; dimethyl phthalate; diethyl phthalate; and the like.

Examples of the sulfoxide-based solvent include dimethyl sulfoxide and diethyl sulfoxide.

Examples of the hydrocarbon-based solvent include: an aliphatic hydrocarbon-based solvent, such as n-pentane, isopentane, n-hexane, isohexane, n-heptane, isoheptane, 2,2,4-trimethylpentane, n-octane, isooctane, cyclohexane, methylcyclohexane, and the like; and an aromatic hydrocarbon-based solvent, such as benzene, toluene, xylene, mesitylene, ethylbenzene, trimethylbenzene, methylethylbenzene, n-propylbenzene, isopropylbenzene, diethylbenzene, isobutylbenzene, triethylbenzene, diisopropylbenzene, n-amylnaphthalene, and the like.

In some embodiments, the organic solvent may be selected from the alcohol-based solvent, the ketone-based solvent, the ester-based solvent, and any combination thereof. In some embodiments, the organic solvent may be selected from 4-methyl-2-pentanol (MIBC), propylene glycol monomethylether, propylene glycol monoethylether, propylene glycol monomethylether acetate, ethyl lactate, cyclohexanone, and any combination thereof.

A weight of the organic solvent may be, based on 100 parts by weight of the resist composition, in a range of about 0 parts by weight to about 99.9 parts by weight. One type of the organic solvent may be used, or a combination of two or more different types of the organic solvent may be used.

### <Optional Component>

The resist composition may further include a surfactant, a cross-linking agent, a leveling agent, a colorant, or any combination thereof, as needed.

The resist composition may further include a surfactant to improve coating properties, developability, and the like. Examples of the surfactant may include a non-ionic surfactant, such as polyoxyethylene lauryl ether, polyoxyethylene stearyl ether, polyoxyethyleneoleyl ether, polyoxyethylene n-octylphenyl ether, polyoxyethylene n-nonylphenyl ether, polyethyleneglycol dilaurate, polyethyleneglycol distearate, and the like. The surfactant may be a commercially available product in the market or a synthetic product. Examples of the commercially available product of the surfactant may include: KP341 (the products of Shin-Etsu Chemical Co., Ltd.); Polyflow No. 75 and Polyflow No. 95 (the products of Kyoeisha Chemical Co., Ltd.); Ftop EF301, Ftop EF303, and Ftop EF352 (manufactured by Mitsubishi Material Electron Chemical Co., Ltd.); MEGAFACE (registered trademark) F171, MEGAFACE F173, R40, R41, and R43 (the products of DIC Corporation); Fluorad (registered trademark) FC430 and Fluorad FC431 (the products of 3M Co, Ltd.); AsahiGuard AG710 (the product of AGC Corporation); Surflon (registered trademark) S-382, Surflon SC-101, Surflon SC-102, Surflon SC-103, Surflon SC-104, Surflon SC-105, and Surflon SC-106 (the products of AGC Seimi Chemical Co., Ltd.).

A weight of the surfactant may be, based on 100 parts by weight of the resist composition, in a range of about 0 parts by weight to about 20 parts by weight. One type of the surfactant may be used, or a combination of two or more different types of the surfactant may be used.

A method of preparing the resist composition is not particularly limited, and for example, a method of mixing a polymer and optional components added as necessary in the organic solvent may be used. During such mixing, a temperature or a time is not particularly limited. If necessary, the mixing may be followed by filtration.

### [Method of Forming Pattern]

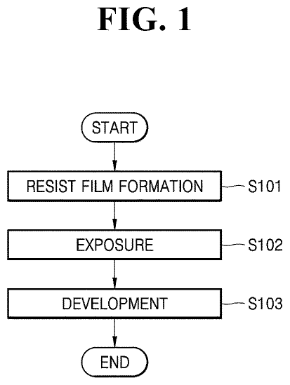

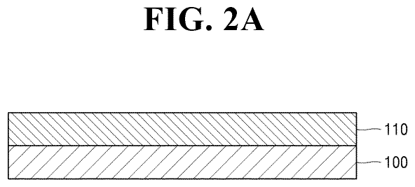

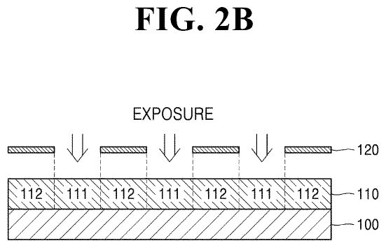

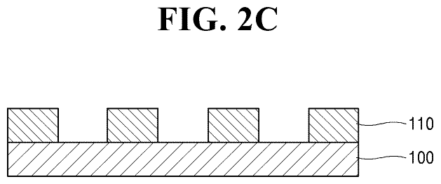

Hereinafter, a method of forming a pattern according to embodiments will be described in more detail with reference to FIGS. 1 and 2A to 2C. FIG. 1 is a flowchart representing a method of forming a pattern according to an embodiment, and FIGS. 2A to 2C are each a side cross-sectional view illustrating a method of forming a pattern according to an embodiment. Hereinafter, a method of forming a pattern using a positive resist composition will be described as an embodiment, but is not limited thereto.

Referring to FIG. 1, a method of forming a pattern may include: forming a resist film by applying a resist composition (S101); exposing at least a portion of the resist film with high-energy rays (S102); and developing the exposed resist film by using a developer (S103). The operations may be omitted if necessary, or may be performed in reverse order.

First, a substrate 100 is prepared. The substrate 100 may be, for example, a semiconductor substrate, such as a silicon substrate or a germanium substrate, or may be formed by using glass, quartz, ceramic, copper, and the like. In an embodiment, the substrate 100 may include a Group III-V compound such as GaP, GaAs, GaSb, and the like.

A resist film 110 may be formed by applying the resist composition onto the substrate 100 to a desired thickness by a coating method. If necessary, heating (pre-baking or a post application baking (PAB)) may be performed to remove an organic solvent remaining in the resist film 110.

Although not particularly limited to a specific theory, cross-links may be formed between the polymer and the organometallic compound by pre-baking. Alternatively, radicals may be formed from the organometallic compound by pre-baking, and then the radicals may form cross-links with a polymer by subsequent exposure.

The coating method may include spin coating, dipping, roller coating, or other common coating methods. Among these methods, spin coating may be particularly used, and the resist film 110 may be formed to a desired thickness by adjusting a viscosity, a concentration, and/or a spinning speed of the resist composition. In some embodiments, a thickness of the resist film 110 may be in a range of about 10 nm to about 300 nm. In some embodiments, the thickness of the resist film 110 may be in a range of about 30 nm to about 200 nm.

A lower limit of a temperature for the pre-baking may be 60° C. or higher, and may be 80° C. or higher. Also, an upper limit of the temperature for the pre-baking may be 240° C. or less and may be 220° C. or less. A lower limit of a time for the pre-baking may be 5 seconds or more and may be 10 seconds or more. An upper limit of a time for the pre-baking may be 600 seconds and may be 300 seconds or less.

Before the resist composition is applied onto the substrate 100, a target film to be etched (not shown) may be additionally formed on the substrate 100. The target film to be etched may refer to a layer on which an image is transferred from a resist pattern and converted into a certain pattern. In an embodiment, the target film to be etched may be formed to include, for example, an insulating material such as silicon oxide, silicon nitride, or silicon oxynitride. In one or more embodiments, the target film to be etched may be formed to include a conductive material such as metal, metal nitride, metal silicide, or metal silicide nitride. In one or more embodiments, the target film to be etched may be formed to include a semiconductor material such as polysilicon.

In an embodiment, an anti-reflection film may be further formed on the substrate 100 to exhibit efficacy of the resist at most. The anti-reflection film may be an organic-based anti-reflection film or an inorganic-based anti-reflection film.

In an embodiment, a protective film may be further provided on the resist film 110 to reduce effects of alkaline impurities included in operations. Also, in the case of immersion exposure, for example, a protective film for immersion may be provided on the resist film 110 to avoid direct contact between an immersion medium and the resist film 110.

Next, at least a portion of the resist film 110 may be exposed to high-energy rays. For example, high-energy rays passing through a mask 120 may be irradiated to at least a portion of the resist film 110. As such, the resist film 110 may include exposed regions 111 and non-exposed regions 112.

Although not particularly limited to a specific theory, radicals are generated in the exposed regions 111 upon exposure, and chemical bonds are formed between the radicals, thereby changing the properties of the resist composition. By exposing the resist film, the main chain of the polymer dissociates and/or the organometallic compound may undergo a condensation reaction.

In some cases, this exposure may be performed by irradiating high-energy rays through a mask having a certain pattern using liquid, such as water, as a medium. Examples of the high-energy rays may include: electromagnetic waves, such as ultraviolet ray, far-ultraviolet rays, extreme ultraviolet rays (EUV rays, wavelength of 13.5 nm), X-rays, γ-rays, and the like; charged particle beams, such as electron beams (EBs), a rays, and the like; and the like. Irradiation of these high-energy rays may be collectively referred to as “exposure”.

For use as a light source of the exposure, various types of irradiation including irradiating laser beams in the ultraviolet region, such as KrF excimer laser (wavelength of 248 nm), ArF excimer laser (wavelength of 193 nm), and F₂ excimer laser (wavelength of 157 nm), irradiating harmonic laser beams in the far ultraviolet or vacuum ultraviolet region by a wavelength conversion method using laser beams from a solid-state laser source (e.g., YAG or semiconductor laser), irradiating electron beams or EUV rays, or the like may be used. Upon the exposure, the exposure may be performed through a mask corresponding to a desired pattern. However, when the light source of the exposure is EBs, the exposure may be performed by direct writing without using a mask.

The integral dose of the high-energy rays may be 2,000 mJ/cm² or less, for example, 500 mJ/cm² or less, in the case of using EUV rays as the high-energy rays. In addition, in the case of using EBs as the high-energy rays, the integral dose of the high-energy rays may be 5,000 μC/cm² or less, for example, 1,000 μC/cm² or less.

In addition, the exposure may be followed by post-exposure baking (PEB). A lower limit of a temperature for the PEB may be 50° C. or more, and may be 80° C. or more. An upper limit of the temperature for the PEB may be 250° C. or less, specifically, 200° C. or less. A lower limit of a time for the PEB may be 5 seconds or more, specifically, 10 seconds or more. An upper limit of the time for the PEB time may be 600 seconds or less or 300 seconds or less.

In an embodiment, the PEB may be omitted.

Next, the exposed resist film 110 may be developed by using a developer. The exposed region 111 may be washed away by the developer, whereas the unexposed region 112 may remain without being washed away by the developer.

Examples of the developer may include an alkaline developer and a developer containing an organic solvent (hereinafter, also referred to as “organic developer”). Examples of the developing method may include a dipping method, a puddle method, a spray method, a dynamic dosing method, and the like. A temperature for the developing may be, for example, 5° C. or more and 60° C. or less, and a time for the developing may be, for example, 5 seconds or more and 300 seconds or less.

The alkaline developer may be, for example, an alkaline aqueous solution which dissolves at least one alkaline compound, such as sodium hydroxide, potassium hydroxide, sodium carbonate, sodium silicate, sodium metasilicate, aqueous ammonia, ethylamine, n-propylamine, diethylamine, di-n-propylamine, triethylamine, methyldiethylamine, ethyldimethylamine, triethanolamine, tetramethyl ammonium hydroxide (TMAH), pyrrole, piperidine, choline, 1,8-diazabicyclo[5.4.0]-7-undecene (DBU), 1,5-diazabicyclo[4.3.0]-5-nonene, and the like. The alkaline developer may further contain a surfactant.

A lower limit of a content of the alkaline compound in the alkaline developer may be 0.1 weight % or more, 0.5 weight % or more, or 1 weight % or more. Also, an upper limit of the content of the alkaline compound in the alkaline developer may be 20 weight % or less, 10 weight % or less, or 5 weight % or less.

For use the organic solvent contained in the organic developer, for example, the same organic solvent as the organic solvent described in the <Organic solvent> of the [Resist composition] may be used. For use as the organic developer, n-butyl acetate (nBA), propylene glycol methyl ether (PGME), propylene glycol methyl ether acetate (PGMEA), γ-butyrolactone (GBL), isopropanol (IPA), and the like may be used. The organic developer may further contain an organic acid such as acetic acid, formic acid, citric acid, and the like.

A lower limit of a content of the organic solvent in the organic developer may be 80 weight % or more, 90 weight % or more, 95 weight % or more, or 99 weight % or more.

The organic developer may contain a surfactant. Also, the organic developer may be present with a trace amount of moisture. Also, upon the development, the development may be stopped by substitution of a different type of solvent from the organic developer.

Following the development, the resist pattern may be further cleaned. Here, ultrapure water, rinsing liquid, and the like may be used as a rinsing liquid. The rinsing liquid is not particularly limited as long as it does not dissolve the resist pattern, and a solution containing a general organic solvent may be used. For example, the rinsing liquid may be an alcohol-based solvent or an ester-based solvent. After the cleansing, the rinsing liquid remaining on the substrate and the resist pattern may be removed. Also, when ultrapure water is used, water remaining on the substrate and the resist pattern may be removed.

In addition, the developer may be one type or two or more types in combination.

After the resist pattern is formed as described above, a patterned interconnection substrate may be obtained. Etching may be performed by known methods such as dry etching using a plasma gas and wet etching using an alkaline solution, a copper (II) chloride solution, an iron (II) chloride solution, or the like.

After the resist pattern is formed, plating may be performed. The plating method is not particularly limited, and examples thereof may include copper plating, solder plating, nickel plating, and gold plating.

The resist pattern remaining after etching may be peeled with an organic solvent. The organic solvent is not particularly limited, and examples thereof may include PGMEA, PGME, ethyl lactate (EL), and the like. A method for peeling is not particularly limited, but examples thereof may include an immersion method, a spray method, and the like. Also, the interconnection substrate on which the resist pattern is formed may be a multi-layer interconnection substrate or may have small-diameter through-holes.

In an embodiment, the interconnection substrate may be formed by a lift-off method in which a resist pattern is formed and then metal is deposited in a vacuum and then the resist pattern is dissolved by using a solution.

### [Method of Forming Patterned Structure]

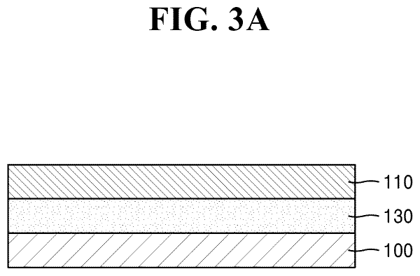

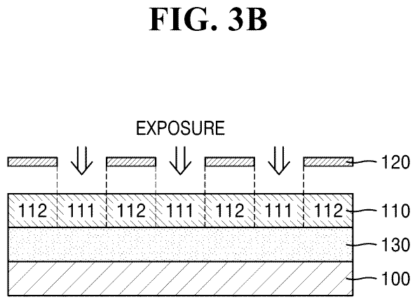

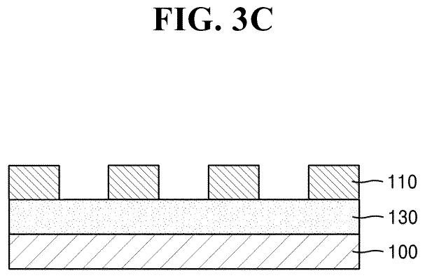

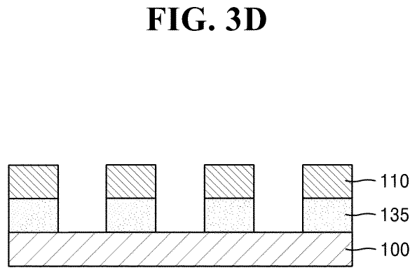

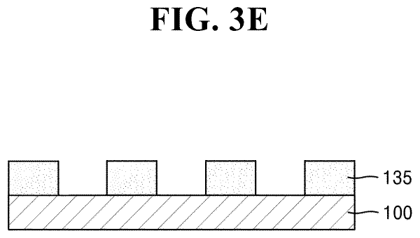

FIGS. 3A to 3E are each a side cross-sectional view illustrating a method of forming a patterned structure according to an embodiment.

As shown in FIG. 3A, a material layer 130 may be formed on the substrate 100 before forming the resist film 110 on the substrate 100. A resist film 110 may be formed on top of the material layer 130. The material layer 130 may include an insulating material (for example, silicon oxide, silicon nitride), a semiconductor material (for example, silicon), or a metal (for example, copper). In some embodiments, the material layer 130 may have a multi-layer structure. The material of the material layer 130 may be different from the material of the substrate 100.

As shown in FIG. 3B, the resist film 110 may go through a pre-exposure bake (PEB) process or the PEB process may be omitted. The resist film 110 may be exposed to high-energy rays through a mask 120, and then the resist film 110 may include exposed regions 111 and unexposed regions 112.

As shown in FIG. 3C, the exposed resist film 110 may be developed using a developer. The exposed regions 111 may be washed away by the developer, and the unexposed regions 112 may remain without being washed away by the developer.

As shown in FIG. 3D, the exposed portion of the material layer 130 may be etched using the resist pattern 110 as a mask to form a material pattern 135 on the substrate 100.

As shown in FIG. 3E, the resist pattern 110 may be removed.

### [Method of Forming Semiconductor Device]

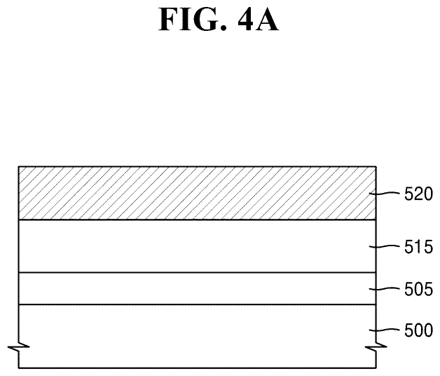

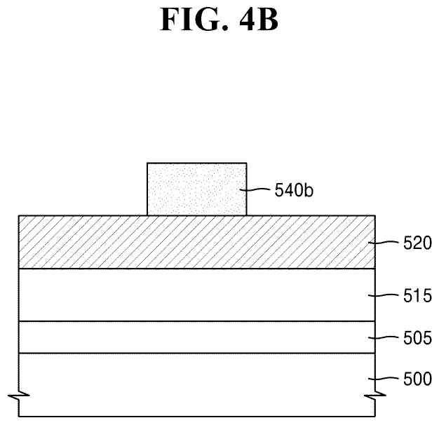

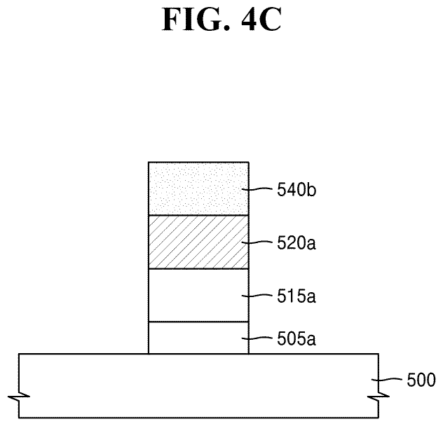

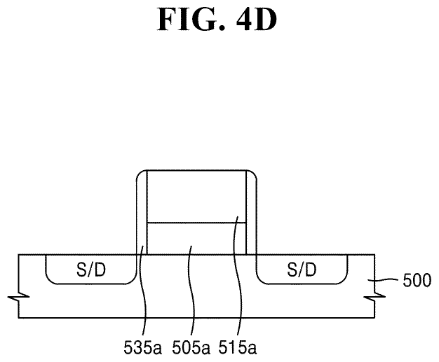

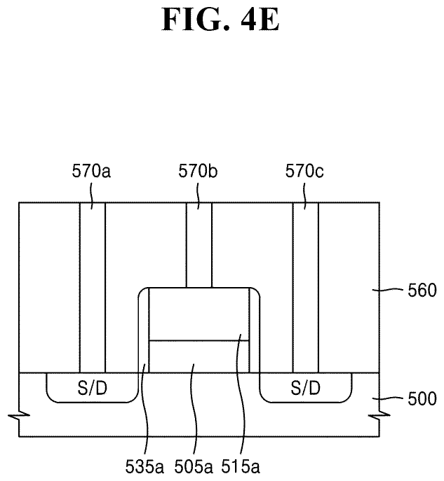

FIGS. 4A to 4E are each a side cross-sectional view illustrating a method of manufacturing a semiconductor device according to an embodiment.

As shown in FIG. 4A, a gate dielectric 505 (for example, silicon oxide) may be formed on a substrate 500. The substrate 500 may be a semiconductor substrate such as a silicon substrate. The gate layer 515 (for example, doped polysilicon) may be formed on gate dielectric 505. A hardmask layer 520 may be formed on the gate layer 515.

As shown in FIG. 4B, a resist pattern 540b may be formed on a hard mask layer 520. The resist pattern 540b may be formed using a resist composition according to an embodiment of the disclosure. The resist composition may include an organic solvent.

As shown in FIG. 4C, the gate layer 515 and the gate dielectric 505 may be etched to form a hard mask pattern 520a, a gate electrode pattern 515a, and a gate dielectric pattern 505a.

As shown in FIG. 4D, the hard mask pattern 520a optionally may be removed and a spacer layer may be formed on the gate electrode pattern 515a and the gate dielectric pattern 505a. The spacer layer may be formed using a deposition process (for example, CVD). The spacer layer may be etched to form a spacer 535a (for example, silicon nitride) on the sidewalls of the gate electrode pattern 515a and the gate dielectric pattern 505a. After forming the spacer 535a, ions may be implanted into the substrate 500 to form source/drain impurity regions (S/D).

As shown in FIG. 4E, an interlayer insulating film 560 (for example, oxide) may be formed on the substrate 500 to cover the gate electrode pattern 515a, the gate dielectric pattern 505a, and the spacer 535a. Thereafter, electrical contact regions 570a, 570b, and 570c connected to the gate electrode 515a and the S/D region may be formed in the interlayer insulating film 560. The electrical contact regions 570a, 570b, and 570c may be formed of a conductive material (for example, metal). Although not shown, a barrier layer may be formed between the sidewall of the interlayer insulating film 560 and the electrical contact regions 570a, 570b, and 570c.

FIGS. 4A to 4E show examples of forming transistors, but the disclosure is not limited thereto.

The resist composition according to an embodiment may be used in a patterning process to form other types of semiconductor devices.

Although not illustrated in FIGS. 4D and 4E, in some embodiments, the hard mask pattern 520a may not be removed before the spacer 535a is formed. For example, if the hard mask pattern 520a is not removed, then the hard mask pattern 520a may remain on the gate electrode 515a in FIGS. 4D and 4E, the spacer 535a may cover a sidewall of the hard mask pattern 520a in FIGS. 4D and 4E, and the electrical contact 570b may extend through an opening in the hard mask pattern 520a to directly contact an upper surface of the gate electrode 515a.

The disclosure will be described in more detail using Examples and Comparative Examples, but the technical scope of the disclosure is not limited to the following examples.

### EXAMPLES

### Synthesis Example 1: Synthesis of OM-A

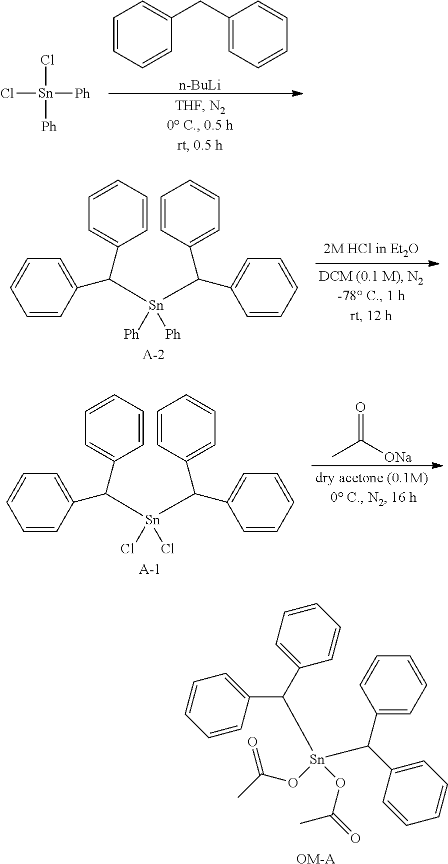

### (1) Synthesis of A-2

In an N₂-substituted 2-necked round-bottom flask, diphenylmethane (4.89 g, 29.1 mmol) was added and diluted therein with THF (30 ml). n-BuLi (2.5 M in hexane, 29.1 mmol) was added dropwise into the round-bottom flask at −78° C. and stirred at 0° C. for 0.5 hours. Dichlorodiphenylstannane (5 g, 14.5 mmol) was added into a vial and diluted therein with THF (28 ml, total THF (58 ml, 0.25 M)). The solution in the vial was added dropwise into the round-bottom flask at −78° C. and stirred for 0.5 hours. Then, the reaction temperature was raised to room temperature, and the mixed solution was stirred again for 0.5 hours. After confirming the completion of the reaction, the solvent was removed and filtered through silica/celite, and the filtrate was purified by column chromatography (ethyl acetate (EA):n-hexane (EA 5 v %)), to obtain A-2 (6.8 g, 77%).

¹H NMR (500 MHZ, CD₂Cl₂) δ4.4 (s, 2H), 6.9-7.3 (m, 30H)

¹³C NMR (126 MHZ, CD₂Cl₂) δ 44.9, 125.6, 128.6, 128.89, 128.92, 129.2, 137.8, 139.6, 142.7

¹¹⁹Sn NMR (186 MHZ, CD₂Cl₂) δ −114.6

### (2) Synthesis of A-1

A-2 (6.2 g, 10.2 mmol) was added to a round-bottom flask which was then substituted with N₂. After diluting therein with dichloromethane (102 ml, 0.1 M), 2 M HCl in Et₂O solution (15.3 ml, 30.67 mmol) was added dropwise into the round-bottom flask at −78° C. After stirring at −78° C. for 1 hour, the reaction solution was raised to room temperature, and the mixed solution was stirred again for 12 hours. After removing the solvent, the precipitated product was obtained by a washing process using methyl t-butyl ether: n-hexane (5 ml: 100 ml) and dried in vacuum, to obtain A-1 (4.3 g, 80%).

¹H NMR (500 MHZ, CD₂Cl₂) δ 4.8 (s, 2H), 7.1-7.4 (m, 20H)

¹³C NMR (126 MHZ, CD₂Cl₂) δ 57.6, 127.5, 129.2, 129.5, 137.8

¹¹⁹Sn NMR (186 MHZ, CD₂Cl₂) δ −36.8

### (3) Synthesis of OM-A

A-1 (1.0 g, 1.91 mmol) was added to a round-bottom flask which was then substituted with N₂. After diluting therein with acetone (19 ml, 0.1 M), sodium acetate (0.31 g, 3.82 mmol) was added to the round-bottom flask at 0° C. A reaction was allowed at 0° C. for 16 hours, and the reaction product was filtered through celite. After removing the solvent, recrystallization was performed (methyl t-butyl ether: n-hexane=3 ml: 30 ml). Following filtration, the precipitated product was dried in vacuum, to obtain OM-A (0.54 g, 50%).

¹H NMR (500 MHZ, CD₂Cl₂) δ 1.7 (s, 6H), 4.7 (s, 2H), 7.1-7.3 (m, 20H)

¹³C NMR (126 MHZ, CD₂Cl₂) δ 19.9, 57.9, 126.7, 128.8, 129.4, 139.0, 182.1

¹¹⁹Sn NMR (186 MHZ, CD₂Cl₂) δ −345.1

### Synthesis Example 2: Synthesis of MCS1

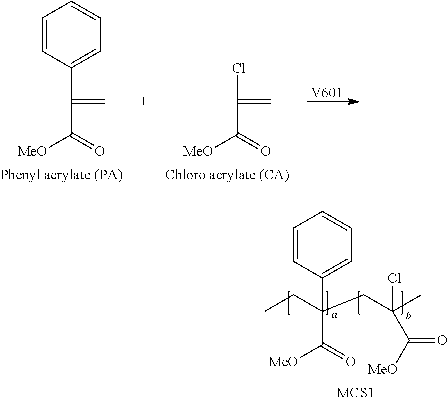

Phenyl acrylate (PA) (1.62 g, 10.0 mmol), V601 (0.5 mmol), chloro acrylate (CA) (1.20 g, 10.0 mmol), and 1,4-dioxane (0.7 g) were added into a vial and allowed for a reaction in a nitrogen atmosphere at 60° C. for 20 hours. After completion of the reaction, the reaction product was precipitated by using n-hexane, to synthesize polymer MCS1. The synthesized polymer was analyzed by ¹H-NMR and gel permeation chromatography (GPC).

¹H-NMR: PA:CA=45:55 (mol:mol)

GPC: Mw 5.7k, PDI 1.38

### Preparation Example: Preparation of Casting Solution

The synthetic product of Synthesis Example 1 was dissolved in cyclopentanone at 3 weight % to prepare Solution 1. The synthetic product of Synthesis Example 2 was dissolved in cyclopentanone at 3 weight % to prepare Solution 2. Then, Solution 1 and Solution 2 were mixed at weight ratios shown in Table 1, to prepare Casting solutions A-1 to A-3 and B-1.]

TABLE 1

| No. of | | | Solution | Organometallic |
|---|---|---|---|---|
| casting | Organometallic | | 1:Solution 2 | compound:polymer |
| solution | compound | Polymer | (weight ratio) | (weight ratio) |
| A-1 | OM-A | MCS1 | 7:3 | 7:3 |
| A-2 | OM-A | MCS1 | 8:2 | 8:2 |
| A-3 | OM-A | MCS1 | 9:1 | 9:1 |
| B-1 | OM-A | MCS1 | 10:0 | 10:0 |

### Evaluation Example 1: Evaluation of Thin Film Phenomenon

### (1) Terminology

In Examples 1-1 to 1-3 and Comparative Example 1-1, E₀ refers to the exposure amount at the point where a thin film is completely developed (e.g., at the point where a thin film is no longer thinning), and E₁ refers to the exposure amount at the point where a thin film begins to be developed.

γ indicates sensitivity, which is calculated by Equation 1:

$$γ = {[ log ( \frac{{E}_{0}}{{E}_{1}} ) ]}^{- 1} \qquad Equation 1$$

### (2) Evaluation of Thin Film Phenomenon

A silicon wafer with HMDS coated as a lower film at a thickness of 3 nm was treated with O₂ plasma for 30 minutes, spin-coated with each of Casting solutions A-1 to A-3 and B-1 at a speed of 1,500 rpm for 1 minute, and then dried (PAB) at 160° C. for 2 minutes, thereby preparing a film. Next, a 3.5 mm-thick zig (4×4) having rectangular holes (1 cm×1 cm) perforated therein was placed on the film obtained by using Casing solutions A-1 to A-3 and B-1, and each hole was exposed to DUV with a wavelength of 254 nm at a dose of 0 mJ/cm² to 40 mJ/cm². The dried film was immersed in a PGMEA solution containing 2 weight % acetic acid dissolved therein as a developer, at 25° C. for 60 seconds, and a thickness of the remaining film was measured. From this, a ratio of the thickness of the remaining thickness to the initial thickness was calculated and represented as a residual film ratio (%) in Table 2.

TABLE 2

| | No. of | | | Organometallic | Initial | | | | Residual |
|---|---|---|---|---|---|---|---|---|---|
| | casting | Organometallic | | compound:polymer | thickness | E1 | E₀ | | film |
| | solution | compound | Polymer | (weight ratio) | (nm) | (mJ/cm²) | (mJ/cm²) | γ | ratio (%) |
| Example 1-1 | A-1 | OM-A | MCS1 | MCS1 | 40 | 2.7 | 4.6 | 4.3 | 0 |
| Example 1-2 | A-2 | OM-A | MCS1 | A-3 | 40 | 2.7 | 4.5 | 4.4 | 0 |
| Example 1-3 | A-3 | OM-A | MCS1 | 9:1 | 40 | 4.8 | 6.5 | 7.4 | ~15 |
| Comparative | B-1 | OM-A | MCS1 | 10:0 | 40 | — | — | — | >70 |
| Example 1-1 | | | | | | | | | |

Referring to Table 2, it was confirmed that, as the ratio of the organometallic compound in the resist composition increases, the residual film ratio also increases so that the properties of the resist are deteriorated, and that, as the ratio of the polymer in the resist composition increases, the sensitivity is improved.

Referring to Table 2, in Comparative Example 1-1, the residual film ratio is high so that E₁, E₀, and γ cannot be specified, and it was confirmed that the properties of a positive resist did not exhibit.

According to example embodiments, a resist composition may have improved storage stability and/or improved sensitivity, and/or may be used to provide a pattern with improved resolution.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the following claims.

What is claimed is:

1. A resist composition comprising:
an organometallic compound represented by Formula 1; and
a polymer including a first repeating unit represented by Formula 2 and a second repeating unit represented by Formula 3, 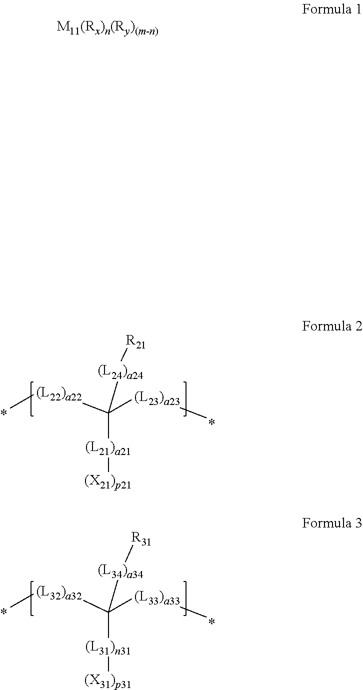
wherein, in Formulae 1 to 3,
M₁₁ is indium (In), tin (Sn), antimony (Sb), tellurium (Te), thallium (Tl), lead (Pb), bismuth (Bi), or polonium (Po),
Rₓ is *-(L₁)ₐ₁-(R₁)_{b1},
R_{y} is *—Y₁—X₁,
n is an integer from 1 to 6,
m is an integer from 0 to 6,
m−n is greater than or equal to 0,
a plurality of Rₓ are identical or different from each other,
a plurality of R_{y} are identical or different from each other,
L₁ is a single bond or a linear, branched, or cyclic C₁-C₃₀ divalent hydrocarbon group,
a1 is an integer from 1 to 4,
R₁ is a substituted or unsubstituted C₁-C₃₀ alkyl group, a substituted or unsubstituted C₃-C₃₀ cycloalkyl group, a substituted or unsubstituted C₃-C₃₀ heterocycloalkyl group, a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group, wherein two adjacent groups among a plurality of R₁ are optionally bound together to form a condensed ring,
b1 is an integer from 1 to 4,
Y₁ is O, O(C═O), S, S(C═O), NX₁₄, or N(C═O),
X₁ and X₁₄ are each independently hydrogen, deuterium, or a linear, branched, or cyclic C₁-C₃₀ monovalent hydrocarbon group that optionally includes a heteroatom,
L₂₁ to L₂₃ are each independently a single bond, O, S, C(═O), C(═O)O, OC(═O), C(═O)NR₂₂, NR₂₂C(═O), S(═O), S(═O)₂, S(═O)₂O, OS(═O)₂, or a linear, branched, or cyclic C₁-C₃₀ divalent hydrocarbon group that optionally includes a heteroatom,
L₃₁ to L₃₃ are each independently a single bond, O, S, C(═O), C(═O)O, OC(═O), C(═O)NR₂₂, NR₂₂C(═O), S(═O), S(═O)₂, S(═O)₂O, OS(═O)₂, or a linear, branched, or cyclic C₁-C₃₀ divalent hydrocarbon group that optionally includes a heteroatom,
L₂₄ is C(═O)O, OC(═O), C(═O)S, SC(═O), OC(═O)O, SC(═O)O, OC(═O)S, SC(═O)S, C(═O)NR₂₂, NR₂₂C(═O), OC(═O)NR₂₂, or NR₂₂C(═O)O,
L₃₄ is C(═O)O, OC(═O), C(═O)S, SC(═O), OC(═O)O, SC(═O)O, OC(═O)S, SC(═O)S, C(═O)NR₃₂, NR₃₂C(═O), OC(═O)NR₃₂, or NR₃₂C(═O)O,
a21 to a24 and a31 to a34 are each independently an integer from 1 to 4,
R₂₁, R₂₂, R₃₁, and R₃₂ are each independently hydrogen, deuterium, or a linear, branched, or cyclic C₁-C₃₀ monovalent hydrocarbon group that optionally includes a heteroatom,
X₂₁ is a substituted or unsubstituted C₂-C₃₀ alkenyl group, a substituted or unsubstituted C₃-C₃₀ cycloalkenyl group, a substituted or unsubstituted C₃-C₃₀ heterocycloalkenyl group, a substituted or unsubstituted C₂-C₃₀ alkynyl group, a substituted or unsubstituted C₆-C₃₀ aryl group, a substituted or unsubstituted C₇-C₃₀ arylalkyl group, a substituted or unsubstituted C₁-C₃₀ heteroaryl group, or a substituted or unsubstituted C₂-C₃₀ heteroarylalkyl group,
X₃₁ is an electron-withdrawing group,
p21 and p31 are each independently an integer from 1 to 5, and
* indicates a binding site to a neighboring atom.

2. The resist composition of claim 1, wherein M₁₁ is In, Sn, or Sb.

3. The resist composition of claim 1, wherein
L₁ is a single bond, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group, and
R₁ is selected from a C₁-C₃₀ alkyl group, a C₃-C₃₀ cycloalkyl group, a C₅-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₇-C₃₀ arylalkyl group, a C₁-C₃₀ heteroaryl group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₅-C₂₀ cycloalkyl group, a C₃-C₂₀ cycloalkoxy group, a C₃-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

4. The resist composition of claim 1, wherein
Y₁ is O, O(C═O), S, or S(C═O), and
X₁ and X₁₄ are each independently selected from: hydrogen; deuterium; and a C₁-C₃₀ alkyl group, a C₁-C₃₀ halogenated alkyl group, a C₁-C₃₀ alkoxy group, a C₁-C₃₀ alkylthio group, a C₁-C₃₀ halogenated alkoxy group, a C₁-C₃₀ halogenated alkylthio group, a C₃-C₃₀ cycloalkyl group, a C₃-C₃₀ cycloalkoxy group, a C₃-C₃₀ cycloalkylthio group, a C₅-C₃₀ heterocycloalkyl group, a C₂-C₃₀ alkenyl group, a C₃-C₃₀ cycloalkenyl group, a C₃-C₃₀ heterocycloalkenyl group, a C₂-C₃₀ alkynyl group, a C₆-C₃₀ aryl group, a C₆-C₃₀ aryloxy group, a C₆-C₃₀ arylthio group, a C₇-C₃₀ arylalkyl group, a C₁-C₃₀ heteroaryl group, a C₁-C₃₀ heteroaryloxy group, a C₁-C₃₀ heteroarylthio group, and a C₂-C₃₀ heteroarylalkyl group, each unsubstituted or substituted with deuterium, a halogen, a cyano group, a nitro group, a hydroxyl group, a thiol group, an amino group, a carboxylate group, an ether moiety, a thioether moiety, a carbonyl moiety, an ester moiety, a phosphonate moiety, a sulfonate moiety, a carbonate moiety, an amide moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₁-C₂₀ alkylthio group, a C₁-C₂₀ halogenated alkoxy group, a C₁-C₂₀ halogenated alkylthio group, a C₃-C₂₀ cycloalkyl group, a C₃-C₂₀ cycloalkoxy group, a C₅-C₂₀ cycloalkylthio group, a C₆-C₂₀ aryl group, a C₁-C₂₀ heteroaryl group, a C₆-C₂₀ aryloxy group, a C₆-C₂₀ arylthio group, a C₁-C₂₀ heteroaryloxy group, a C₁-C₂₀ heteroarylthio group, or any combination thereof.

5. The resist composition of claim 1, wherein
the organometallic compound represented by Formula 1 is represented by one of Formulae 1-1 to 1-4: 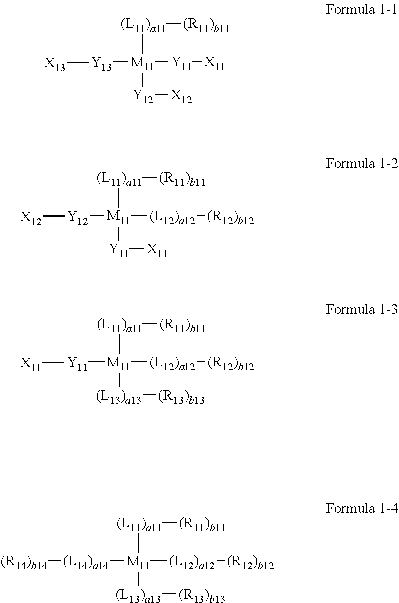
wherein, in Formulae 1-1 to 1-4,
M₁₁ is as defined in Formula 1,
L₁₁ to L₁₄ are each independently defined as for L₁ in Formula 1,
a11 to a14 are each independently defined as for a1 in Formula 1,
R₁₁ to R₁₄ are each independently defined as for R₁ in Formula 1,
b11 to b14 are each independently defined as for b1 in Formula 1,
Y₁₁ to Y₁₃ are each independently defined as for Y₁ in Formula 1, and
X₁₁ to X₁₃ are each independently defined as for X₁ in Formula 1.

6. The resist composition of claim 1, wherein
the organometallic compound represented by Formula 1 is selected from Group I: 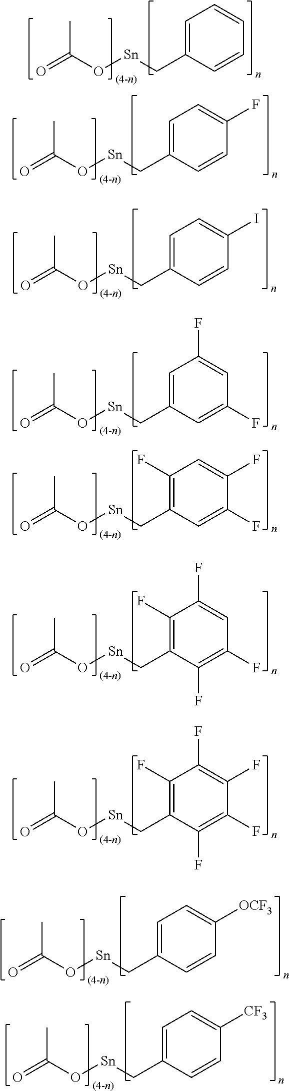 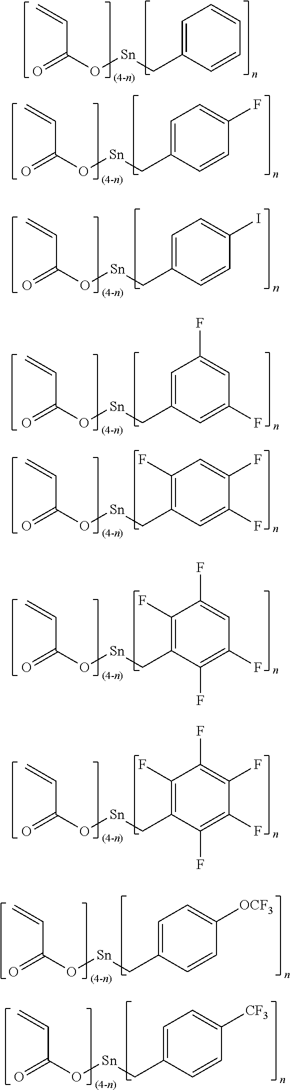 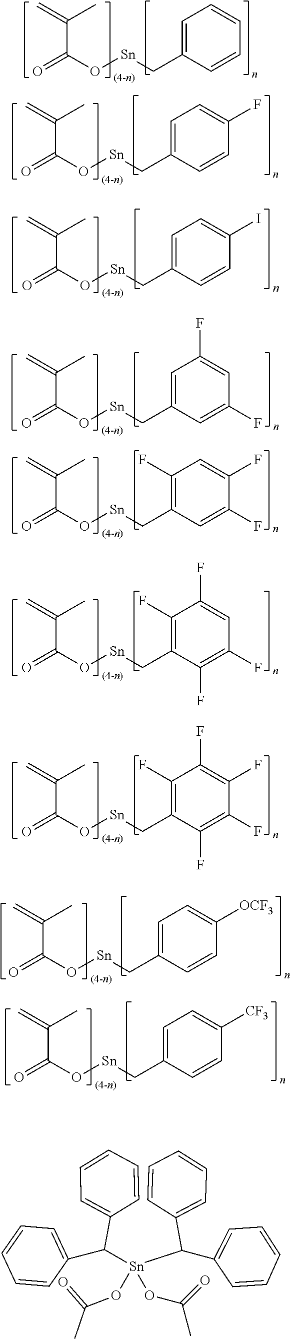 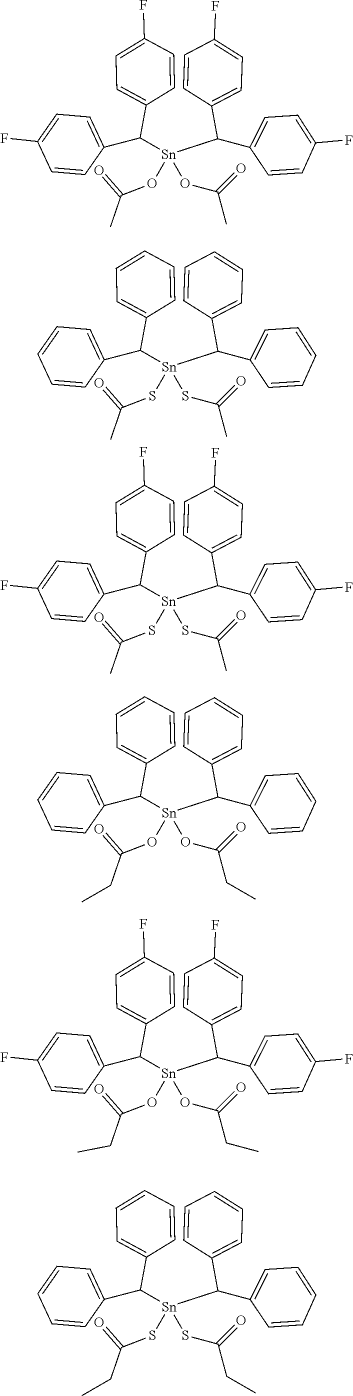 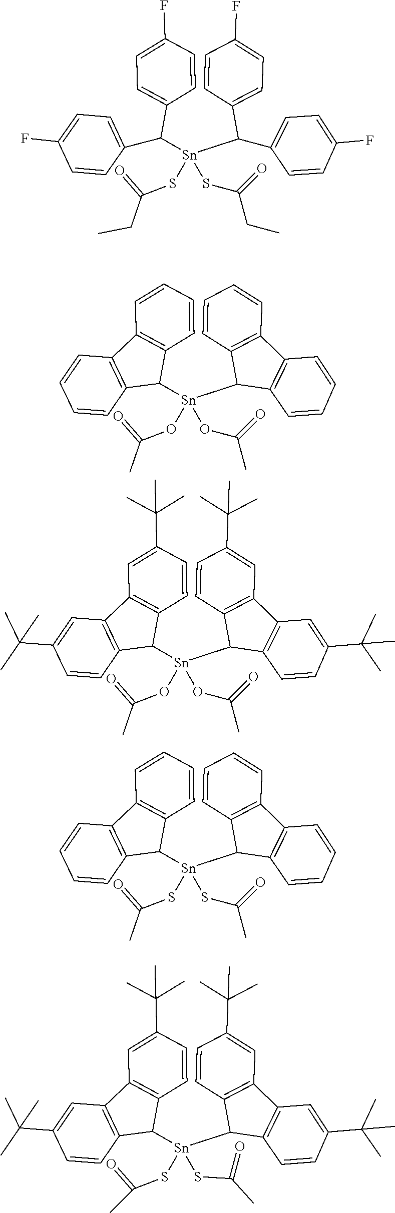 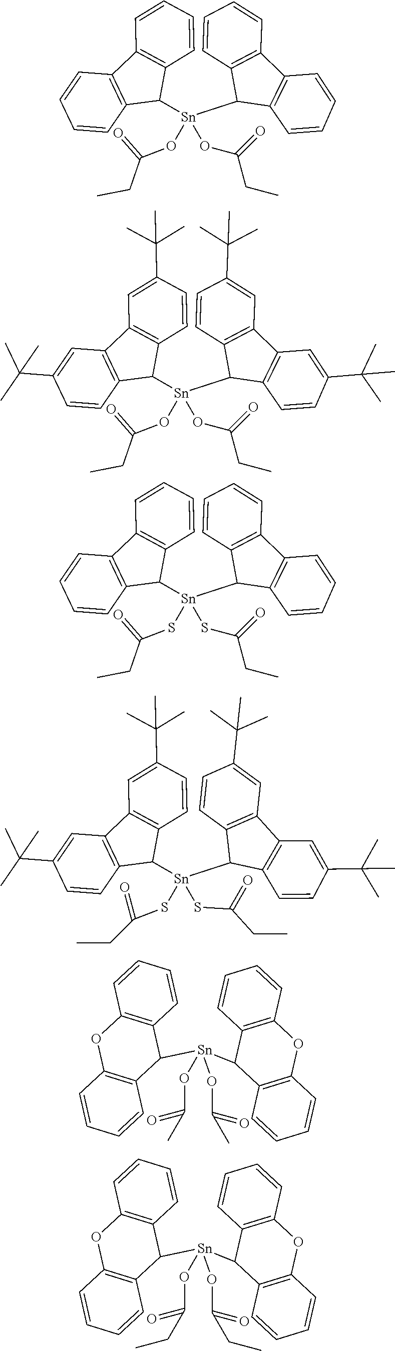 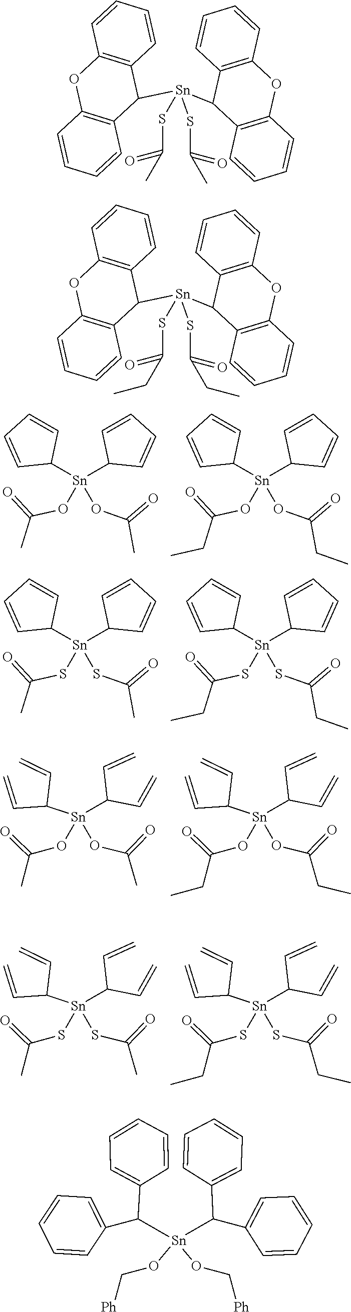 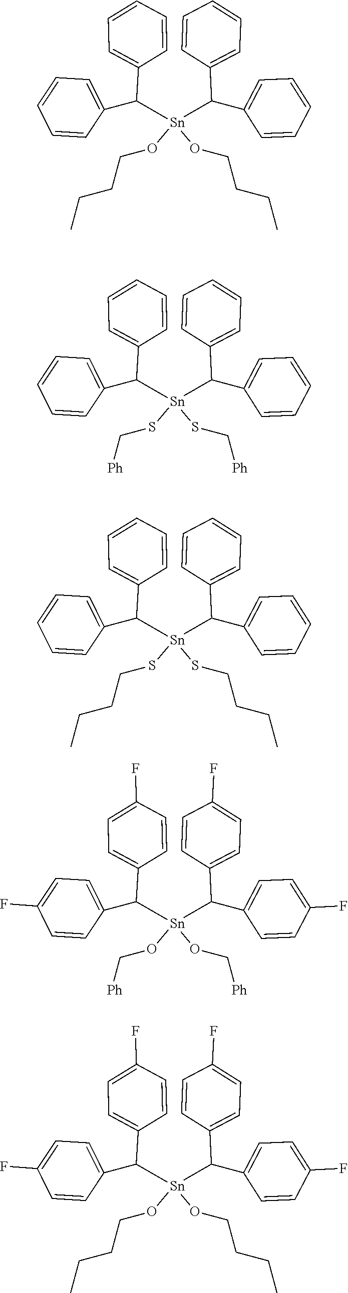 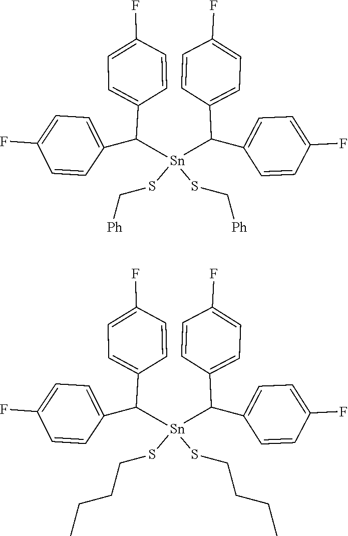 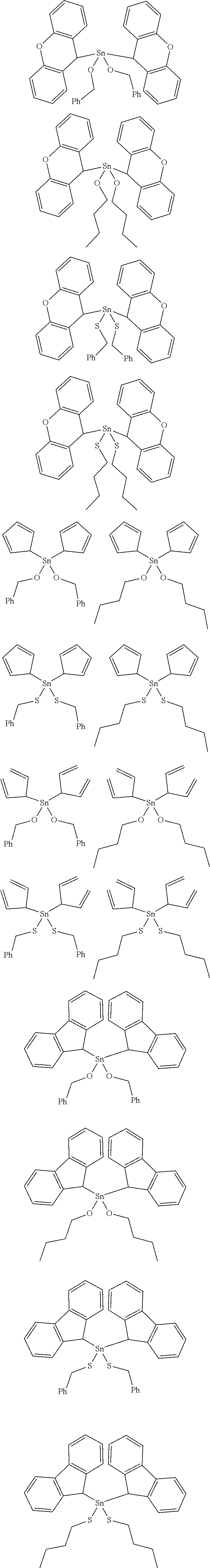 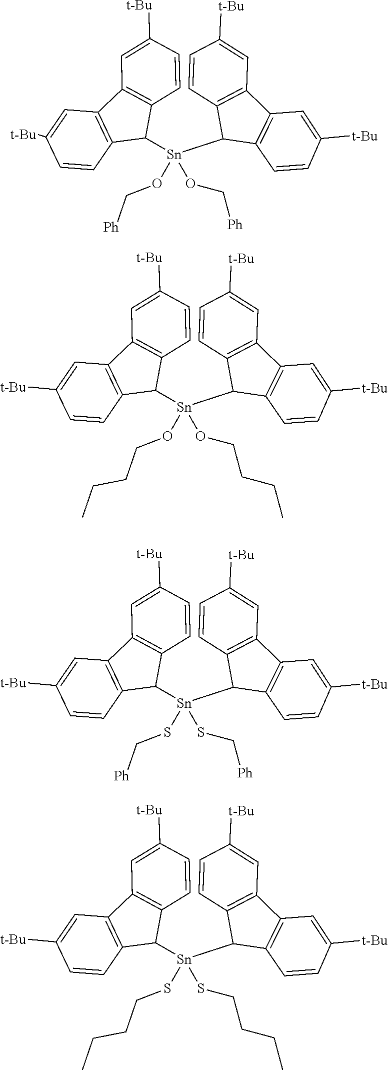
wherein, in Group I, n is an integer from 1 to 4.

7. The resist composition of claim 1, wherein
L₂₁ to L₂₃ and L₃₁ to L₃₃ are each independently a single bond, O, S, C(═O), C(═O)O, OC(═O), C(═O)NH, NHC(═O), S(═O), S(═O)₂, S(═O)₂O, OS(═O)₂, a substituted or unsubstituted C₁-C₃₀ alkylene group, a substituted or unsubstituted C₃-C₃₀ cycloalkylene group, a substituted or unsubstituted C₃-C₃₀ heterocycloalkylene group, a substituted or unsubstituted C₂-C₃₀ alkenylene group, a substituted or unsubstituted C₃-C₃₀ cycloalkenylene group, a substituted or unsubstituted C₃-C₃₀ heterocycloalkenylene group, a substituted or unsubstituted C₆-C₃₀ arylene group, or a substituted or unsubstituted C₁-C₃₀ heteroarylene group, and
L₂₄ and L₃₄ are each independently C(═O)O, OC(═O), C(═O)S, SC(═O), C(═O)NH, C(═O)NCH₃, NHC(═O), or NCH₃C(═O).

8. The resist composition of claim 1, wherein R₂₁, R₂₂, R₃₁, and R₃₂ are each independently selected from:
hydrogen; deuterium; and a C₁-C₂₀ alkyl group, a C₅-C₂₀ cycloalkyl group, and a C₆-C₂₀ aryl group, each unsubstituted or substituted with deuterium, a halogen, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₅-C₂₀ cycloalkyl group, a C₃-C₂₀ cycloalkoxy group, a C₆-C₂₀ aryl group, or any combination thereof.

9. The resist composition of claim 1, wherein
X₂₁ is selected from a C₂-C₂₀ alkenyl group, a C₃-C₂₀ cycloalkenyl group, a C₂-C₂₀ alkynyl group, and a C₆-C₂₀ aryl group, each unsubstituted or substituted with deuterium, a halogen, a cyano group, a hydroxyl group, an amino group, a carboxylate group, a thiol group, an ester moiety, a sulfonate ester moiety, a carbonate moiety, a carbamate moiety, a lactone moiety, a sultone moiety, a carboxylic anhydride moiety, a C₁-C₂₀ alkyl group, a C₁-C₂₀ halogenated alkyl group, a C₁-C₂₀ alkoxy group, a C₃-C₂₀ cycloalkyl group, a C₅-C₂₀ cycloalkoxy group, a C₆-C₂₀ aryl group, or any combination thereof.

10. The resist composition of claim 1, wherein X₃₁ is selected from: a halogen; a cyano group; and a C₁-C₃₀ alkyl group, a C₃-C₃₀ cycloalkyl group, a C₂-C₃₀ alkenyl group, a C₃-C₃₀ cycloalkenyl group, a C₂-C₃₀ alkynyl group, a C₆-C₃₀ aryl group, and a C₇-C₃₀ arylalkyl group, each unsubstituted or substituted with a halogen, a cyano group, a C₁-C₂₀ halogenated alkyl group, or any combination thereof.

11. The resist composition of claim 1, wherein
the first repeating unit is selected from Group II, and
the second repeating unit is selected from Group III: 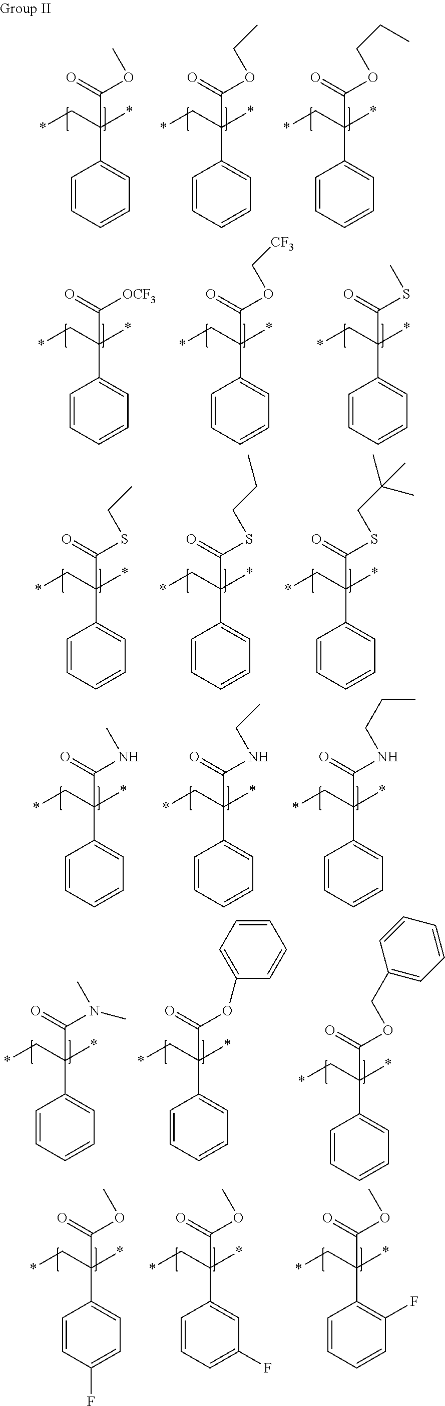 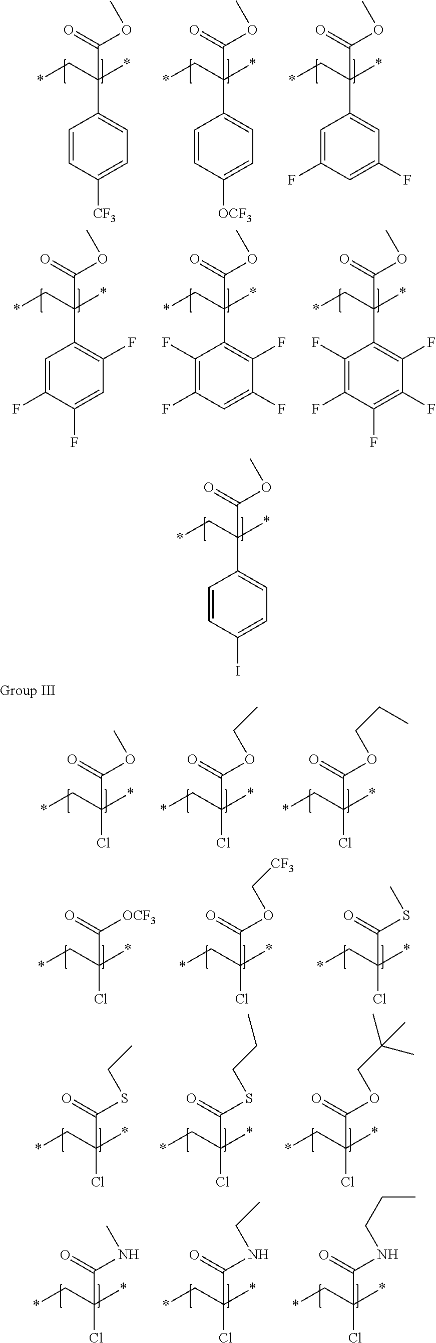 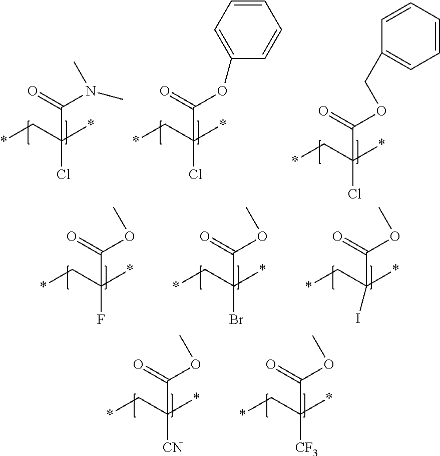
wherein, in Group II and Group III, * indicates a binding site to a neighboring atom.

12. The resist composition of claim 1, wherein, in the resist composition, a weight of the organometallic compound is greater than or equal to a weight of the polymer.

13. The resist composition of claim 1, wherein a weight ratio of the organometallic compound to the polymer is in a range of about 9:1 to about 5:5.

14. A method of forming a pattern, the method comprising:
forming a resist film by applying the resist composition of claim 1 on a substrate;
exposing at least a portion of the resist film to high-energy rays; to provide an exposed resist film and
developing the exposed resist film by using a developer.

15. The method of claim 14, wherein the exposing the at least a portion of the resist film is performed by irradiating at least one of deep ultraviolet (DUV) rays, extreme ultraviolet (EUV) rays, or electron beams (EBs).

16. The method of claim 14, wherein a main chain of the polymer is decomposed by the exposing the resist film.

17. The method of claim 14, wherein the organometallic compound undergoes a condensation reaction by the exposing the resist film.

18. The method of claim 14, further comprising:
before the exposing, heating the resist film.

19. The method of claim 18, wherein, the heating the resist film forms a cross-link between the polymer and the organometallic compound.

20. The method of claim 14, wherein
the exposed resist film includes an exposed region and a non-exposed region, and
the exposed region is removed by the developing of the exposed resist film.
